(19) United States
(12) Patent Application Publication
(10) Pub. No.: US 2024/0224694 A1
(43) Pub. Date: Jul. 4, 2024

(54) DISPLAY DEVICE

(71) Applicant: Samsung Display Co., LTD., Yongin-si (KR)

(72) Inventors: SEON UK LEE, Yongin-si (KR); SEUNGKIL YANG, Yongin-si (KR); DONCHAN CHO, Yongin-si (KR)

(21) Appl. No.: 18/403,379

(22) Filed: Jan. 3, 2024

(30) Foreign Application Priority Data
Jan. 4, 2023 (KR) 10-2023-0001299

(51) Int. Cl. H10K 59/38; H10K 59/122; H10K 102/00

(52) U.S. Cl. CPC H10K 59/38; H10K 59/122; H10K 2102/331

(57) ABSTRACT

A display device includes: a first substrate including a first light emitting area, a second light emitting area, and a third light emitting area that are configured to emit light of different colors, respectively; a light emitting element on the first substrate and overlapping each of the first, second, and third emitting areas; a bank layer on the light emitting element and defining a first opening overlapping the first light emitting area, a second opening overlapping the second light emitting area, and a third opening overlapping the third light emitting area; and an optical filter filling the first, second, and third openings, wherein each of the first opening and the third opening has a rectangular planar shape and the second opening has an “L” shape planer shape.

### CROSS-REFERENCE TO RELATED APPLICATION

The present application claims priority to and benefits of Korean Patent Application No. 10-2023-0001299, filed on Jan. 4, 2023, in the Korean Intellectual Property Office (KIPO), the entire content of which is incorporated herein by reference.

### BACKGROUND

### 1. Field

Aspects of some embodiments relate generally to a display device.

### 2. Description of the Related Art

In recent years, a flat panel display (FPD), which has a relatively large area and can be relatively thin and lightweight, has been widely used as a display device for various electronic products. As the flat panel display, a liquid crystal display (LCD), a plasma display panel (PDP), an organic light emitting display (OLED), and the like may be used.

Recently, an organic light emitting display device including an organic light emitting element and a color conversion layer has been researched. The color conversion layer may convert a wavelength of light emitted from the organic light emitting element. Accordingly, the organic light emitting display device may emit light having a color different from a color of incident light.

The above information disclosed in this Background section is only for enhancement of understanding of the background and therefore the information discussed in this Background section does not necessarily constitute prior art.

### SUMMARY

Aspects of some embodiments relate generally to a display device. For example, aspects of some embodiments include a display device that provides visual information.

Aspects of some embodiments include a display device with relatively improved display quality.

A display device according to some embodiments of the present disclosure includes a first substrate including a first light emitting area, a second light emitting area, and a third light emitting area that emit light of different colors, a light emitting element on the first substrate and overlapping each of the first, second, and third emitting areas, a bank layer on the light emitting element and defining a first opening overlapping the first light emitting area, a second opening overlapping the second light emitting area, and a third opening overlapping the third light emitting area, and an optical filter filling the first, second, and third openings. Each of the first opening and the third opening may have a rectangular planar shape and the second opening may have an “L” shape planer shape.

According to some embodiments, the second opening may have a planar shape surrounding at least a part of the third opening.

According to some embodiments, the second opening may have an “L” shape planar shape rotated clockwise by about 90 degrees.

According to some embodiments, the first, second, and third openings may at least partially overlap each other in a first direction and the third opening may at least partially overlap with the second opening in a second direction perpendicular to the first direction.

According to some embodiments, the second opening may have a first area and a second area protruding from the first area in a direction opposite to the second direction. According to some embodiments, the third opening may partially overlap the first area in the second direction and partially overlap the second area in the first direction.

According to some embodiments, the first light emitting area, the second light emitting area, and the third light emitting area may be repeatedly arranged in an order of the first light emitting area, the second light emitting area, and the third light emitting area along the first direction.

According to some embodiments, the first emitting area may have a same planar shape as the first opening, the second emitting area may have a same planar shape as the second opening, and the third emitting area may have a same planar shape as the third opening.

According to some embodiments, a width of the bank layer between two adjacent openings among the first, second, and third openings may be about 5 μm to about 25 μm.

According to some embodiments, the first light emitting area may emit red light, the second emitting area may emit green light, and the third light emitting area may emit blue light.

According to some embodiments, an area of the first light emitting area may be greater than or equal to an area of the second light emitting area and the area of the second light emitting area may be greater than an area of the third light emitting area.

According to some embodiments, the optical filter may include a first color conversion layer filling the first opening and including quantum dot, a second color conversion layer filling the second opening and including quantum dot, and a light transmission layer filling the third opening.

According to some embodiments, the display device may further include a second substrate on the optical filter, a first color filter between the second substrate and the first color conversion layer, and overlapping the first light emitting area, a second color filter between the second substrate and the second color conversion layer, and overlapping the second light emitting area, and a third color filter between the second substrate and the light transmission layer, and overlapping the second light emitting area.

According to some embodiments, a (1-1)th opening overlapping the second light emitting area and a (2-1)th opening overlapping the third light emitting area may be defined in the first color filter, a (1-2)th opening exposing a part of an upper surface of the first color filter in the first light emitting area and a (2-2)th opening connected to the (2-1)th opening may be defined in the second color filter, and a (1-3)th opening connected to the (1-1)th opening and a (2-3)th opening exposing a part of an upper surface of the second color filter in second light emitting area may be defined in the third color filter.

A display device according to some embodiments of the present disclosure includes a first substrate including a first light emitting area, a second light emitting area, and a third light emitting area that emit light of different colors, a light emitting element on the first substrate and overlapping each of the first, second, and third emitting areas, a bank layer on the light emitting element and defining a first opening overlapping the first light emitting area, a second opening overlapping the second light emitting area, and a third opening overlapping the third light emitting area, and an optical filter filling the first, second, and third openings. The third opening may have a rectangular planar shape and each of the first opening and the second opening may have an “L” shape planer shape.

According to some embodiments, the first opening may have a planar shape surrounding at least a part of the second opening and the second opening may have a planar shape surrounding at least a part of the first opening.

According to some embodiments, the second opening may have an “L” shape planar shape rotated by about 180 degrees in a counterclockwise direction or a clockwise direction.

According to some embodiments, the first opening may have an “L” shape planar shape rotated 90 degrees clockwise and the second opening may have an “L” shape planar shape rotated 90 degrees counterclockwise direction.

According to some embodiments, the first, second, and third openings may at least partially overlap each other in a first direction and the first and second openings may at least partially overlap each other in a second direction perpendicular to the first direction.

According to some embodiments, the first and second light emitting areas may be repeatedly arranged along the second direction in odd-numbered columns and the third light emitting area may be repeatedly arranged along the second direction in even-numbered columns.

According to some embodiments, the first emitting area may have a same planar shape as the first opening, the second emitting area may have a same planar shape as the second opening, and the third emitting area may have a same planar shape as the third opening.

According to some embodiments, the first light emitting area may emits red light, the second emitting area may emit green light, and the third light emitting area may emits blue light.

According to some embodiments, an area of the first light emitting area may be greater than or equal to an area of the second light emitting area and the area of the second light emitting area may be greater than an area of the third light emitting area.

According to some embodiments, the optical filter may include a first color conversion layer filling the first opening and including quantum dot, a second color conversion layer filling the second opening and including quantum dot, and a light transmission layer filling the third opening.

According to some embodiments, the display device may further include a second substrate on the optical filter, a first color filter between the second substrate and the first color conversion layer, and overlapping the first light emitting area, a second color filter between the second substrate and the second color conversion layer, and overlapping the second light emitting area, and a third color filter between the second substrate and the light transmission layer, and overlapping the second light emitting area.

A display device according to some embodiments includes a bank layer defining a first opening overlapping a first light emitting area that emits red light, a second opening overlapping a second light emitting area that emits green light, and a third opening overlapping a third light emitting area that emits blue light. Each of the at least two openings including the second opening among the first, second, and third openings may have an “L” shape planar shape, and the remaining openings may have a rectangular planar shape. Accordingly, coloration of the display device may be relatively improved, and inkjet yield may be relatively improved in an inkjet printing process of forming an optical filter.

### BRIEF DESCRIPTION OF THE DRAWINGS

Illustrative, aspects of some non-limiting embodiments will be more clearly understood from the following detailed description in conjunction with the accompanying drawings.

FIG. 1 is a perspective view illustrating a display device according to some embodiments of the present disclosure.

FIG. 2 is a cross-sectional view taken along the line I-I′ of FIG. 1.

FIG. 3 is a plan view illustrating an example of the display device of FIGS. 1 and 2.

FIG. 4 is a plan view illustrating an example of a pixel defining layer of an array substrate of FIGS. 1 and 2.

FIG. 5 is a plan view illustrating an example of a bank layer of a color conversion substrate of FIGS. 1 and 2.

FIG. 6 is an enlarged plan view of area A of FIG. 5.

FIG. 7 is a cross-sectional view taken along the line II-II′ of FIG. 3.

FIG. 8 is a cross-sectional view illustrating a first color conversion layer, a second color conversion layer, and a light transmission layer of the display device of FIG. 7.

FIGS. 9, 10, 11, 12, 13, 14, 15, 16, 17 18, 19, and 20 are cross-sectional views for explaining a method of manufacturing the display device of FIG. 7.

FIG. 21 is a plan view illustrating another example of the display device of FIGS. 1 and 2.

FIG. 22 is a plan view illustrating another example of a pixel defining layer of an array substrate of FIGS. 1 and 2.

FIG. 23 is a plan view illustrating another example of a bank layer of a color conversion substrate of FIGS. 1 and 2.

FIG. 24 is a plan view illustrating another example of the display device of FIGS. 1 and 2.

FIG. 25 is a plan view illustrating another example of a pixel defining layer of an array substrate of FIGS. 1 and 2.

FIG. 26 is a plan view showing another example of a bank layer of a color conversion substrate of FIGS. 1 and 2.

FIG. 27 is a cross-sectional view illustrating a display device according to some embodiments of the present disclosure.

### DETAILED DESCRIPTION

Hereinafter, a display device according to some embodiments of the present disclosure will be explained in more detail with reference to the accompanying drawings. The same reference numerals are used for the same components in the drawings, and redundant descriptions of the same components will be omitted.

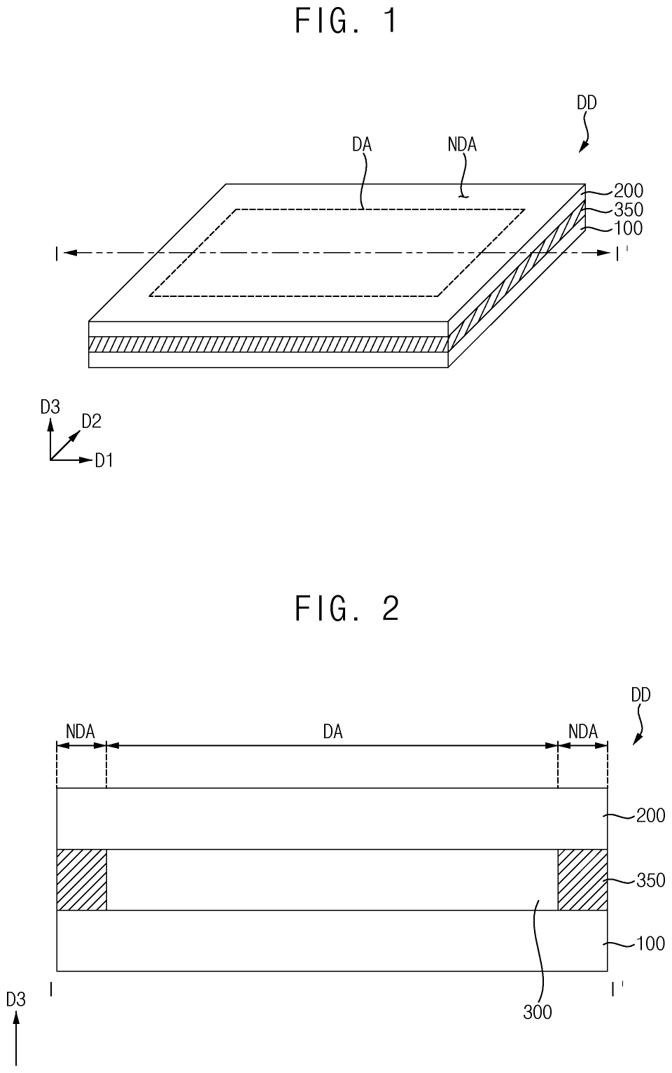

FIG. 1 is a perspective view illustrating a display device according to some embodiments of the present disclosure. FIG. 2 is a cross-sectional view taken along the line I-I′ of FIG. 1.

Referring to FIGS. 1 and 2, a display device DD according to some embodiments of the present disclosure may include an array substrate 100, a sealing portion 350, a filling layer 300, and a color conversion substrate 200.

The display device DD may be divided into a display area DA and a non-display area NDA. The display area DA may be defined as an area for displaying images, and the non-display area NDA may be defined as an area not displaying images. The non-display area NDA may be positioned around (e.g., in a periphery or outside a footprint of) the display area DA. For example, the non-display area NDA may surround the display area DA.

The array substrate 100 may include a substrate, insulating layers, a transistor, a light emitting element, and the like. Further detailed description of the array substrate 100 will be described later.

The color conversion substrate 200 may be located on the array substrate 100. The color conversion substrate 200 may face the array substrate 100. The color conversion substrate 200 may include a color conversion layer that converts a wavelength of light emitted from the light emitting element (e.g., to a different wavelength of light). Further detailed description of the color conversion substrate 200 will be described later.

The sealing portion 350 may be located between the array substrate 100 and the color conversion substrate 200 in the non-display area NDA. The sealing portion 350 may be arranged along the edges of the array substrate 100 and the color conversion substrate 200 in the non-display area NDA to surround the display area DA in a plan view (e.g., a view that is normal or perpendicular with respect to a display surface of the display device DD). That is, according to some embodiments, the sealing portion 350 may not overlap the display area in a plan view. In addition, the array substrate 100 and the color conversion substrate 200 may be coupled through the sealing portion 350. The sealing portion 350 may include an organic material. For example, the sealing portion 350 may include an epoxy resin and the like. However, embodiments according to the present disclosure are not limited thereto, and the sealing portion 350 may include various organic materials.

The filling layer 300 may be located between the array substrate 100 and the color conversion substrate 200. The filling layer 300 may fill a space between the array substrate 100 and the color conversion substrate 200. The filling layer 300 may include a material capable of transmitting light (e.g., allowing light to pass therethrough). For example, the filling layer 300 may include an organic material. Examples of materials that can be used for the filling layer 300 include silicone-based resin, epoxy-based resins, and the like. These may be used alone or in combination with each other. However, embodiments according to the present disclosure are not limited thereto, and the filling layer 300 may include various organic materials. In other embodiments, the filling layer 300 may be omitted.

In this specification, a plane may be defined as a first direction D1 and a second direction D2 crossing the first direction D1. For example, the second direction D2 may be perpendicular to the first direction D1. In addition, a third direction D3 may be perpendicular to the plane. According to some embodiments, a plane defined by the first direction D1 and the second direction D2 may be parallel to a plane of the display surface of the display device DD.

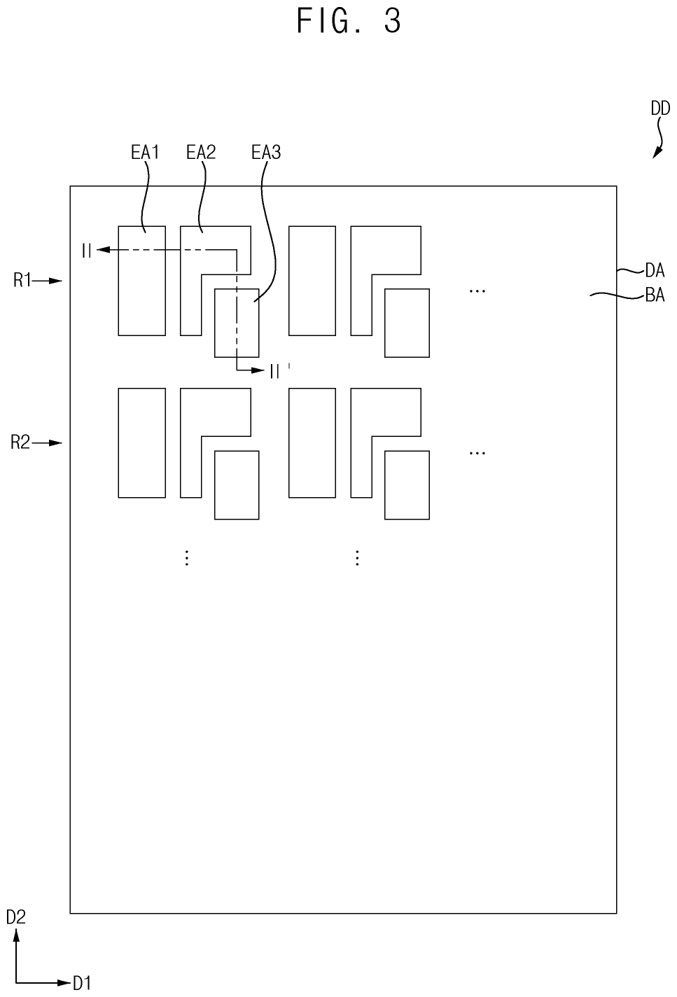

FIG. 3 is a plan view illustrating an example of the display device of FIGS. 1 and 2.

Referring to FIG. 3, the display area DA of the display device DD according to some embodiments may include a first light emitting area EA1, a second light emitting area EA2, a third light emitting area EA3, and a light blocking area BA.

Each of the first light emitting area EA1, the second light emitting area EA2, and the third light emitting area EA3 may be an area through which light emitted from the light emitting element is emitted to the outside (e.g., in the third direction D3). The first light emitting area EA1, the second light emitting area EA2, and the third light emitting area EA3 may emit light of different colors, respectively. For example, the first light emitting area EA1 may emit light of a first color, the second light emitting area EA2 may emit light of a second color, and the third light emitting area EA3 may emit light of a third color.

According to some embodiments, the first light emitting area EA1 may emit red light, the second light emitting area EA2 may emit green light, and the third light emitting area EA3 may emit blue light. However, embodiments of the present disclosure are not limited thereto, and for example, the first light emitting area EA1, the second light emitting area EA2, and the third light emitting area EA3 may be combined to emit yellow, cyan, and magenta lights.

In addition, the first light emitting area EA1, the second light emitting area EA2, and the third light emitting area EA3 may emit light of four or more colors. For example, the first light emitting area EA1, the second light emitting area EA2, and the third light emitting area EA3 may be combined to further emit at least one of yellow, cyan, or magenta lights in addition to red, green, and/or blue lights. In addition, the first light emitting area EA1, the second light emitting area EA2, and the third light emitting area EA3 may be combined to further emit white light.

The first light emitting area EA1, the second light emitting area EA2, and the third light emitting area EA3 may be repeatedly arranged along the first direction D1 and the second direction D2. According to some embodiments, light emitting areas that emit light of the same color may be repeatedly arranged along the second direction D2, and light emitting areas that emit light of different colors may be repeatedly arranged along the first direction D1.

For example, the first light emitting area EA1, the second light emitting area EA2, and the third light emitting area EA3 may be repeatedly arranged in an order of the first light emitting area EA1, the second light emitting area EA2, and the third light emitting area EA3 along the first direction D1 in a first row R1. Similarly, the first light emitting area EA1, the second light emitting area EA2, and the third light emitting area EA3 may be repeatedly arranged in an order of the first light emitting area EA1, the second light emitting area EA2, and the third light emitting area EA3 along the first direction D1 in a second row R2 adjacent to the first row R1. Here, the first direction D1 may be a row direction, and the second direction D2 may be a column direction. The arrangement of the light emitting areas may be repeated up to a row (e.g., a set or predetermined row).

Areas of the first light emitting area EA1, the second light emitting area EA2, and the third light emitting area EA3 may be different from each other. According to some embodiments, the area of the first light emitting area EA1 that emits red light may be greater than the area of each of the second light emitting area EA2 that emits green light and the third light emitting area EA3 that emits blue light. In this case, the area of the second light emitting area EA2 may be greater than the area of the third light emitting area EA3. According to some embodiments, the area of the first light emitting area EA1 that emits red light may be the same as the area of the second light emitting area EA2 that emits green light and may be greater than the area of the third light emitting area EA3 that emits blue light.

According to some embodiments, each of the first light emitting area EA1 and the third light emitting area EA3 may have a rectangular planar shape, and the second light emitting area EA2 may have an “L” shape planar shape rotated by about 90 degrees in a clockwise direction. For example, the second light emitting area EA2 may have an “L” shape planar shape rotated by 90 degrees in a clockwise direction to surround at least a part of the third light emitting area EA3.

According to some embodiments, the first light emitting area EA1, the second light emitting area EA2, and the third light emitting area EA3 may at least partially overlap each other in the first direction D1. In addition, the second light emitting area EA2 and the third light emitting area EA3 may at least partially overlap each other in the second direction D2. That is, the third light emitting area EA3 may overlap the second light emitting area EA2 in the first direction D1 and the second direction D2 and may only overlap the first light emitting area EA1 in the first direction D1.

The light blocking area BA may be positioned between the first light emitting area LA1, the second light emitting area LA2, and the third light emitting area LA3. For example, in a plan view, the light blocking area BA may surround the first light emitting area LA1, the second light emitting area LA2, and the third light emitting area LA3. The light blocking area BA may not emit light.

The display device DD may have a rectangular planar shape. For example, the display device DD may include two first sides extending in the first direction D1 and two second sides extending in the second direction D2. A corner where the first side and the second side meet may be a right angle. According to some embodiments, a corner where the first side and the second side of the display device DD meet may form a curved surface.

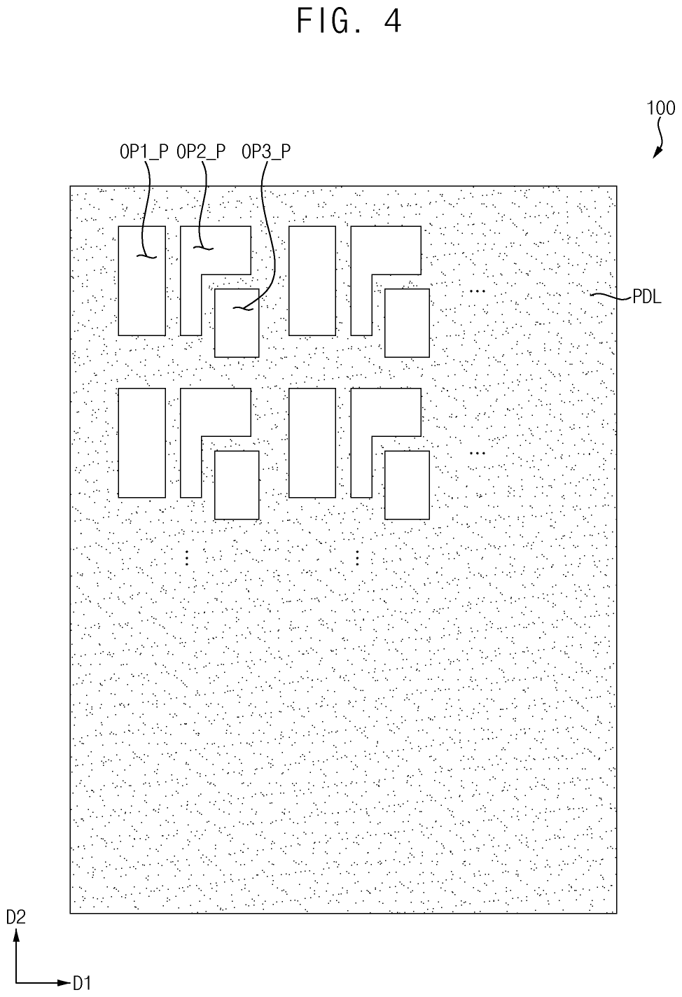

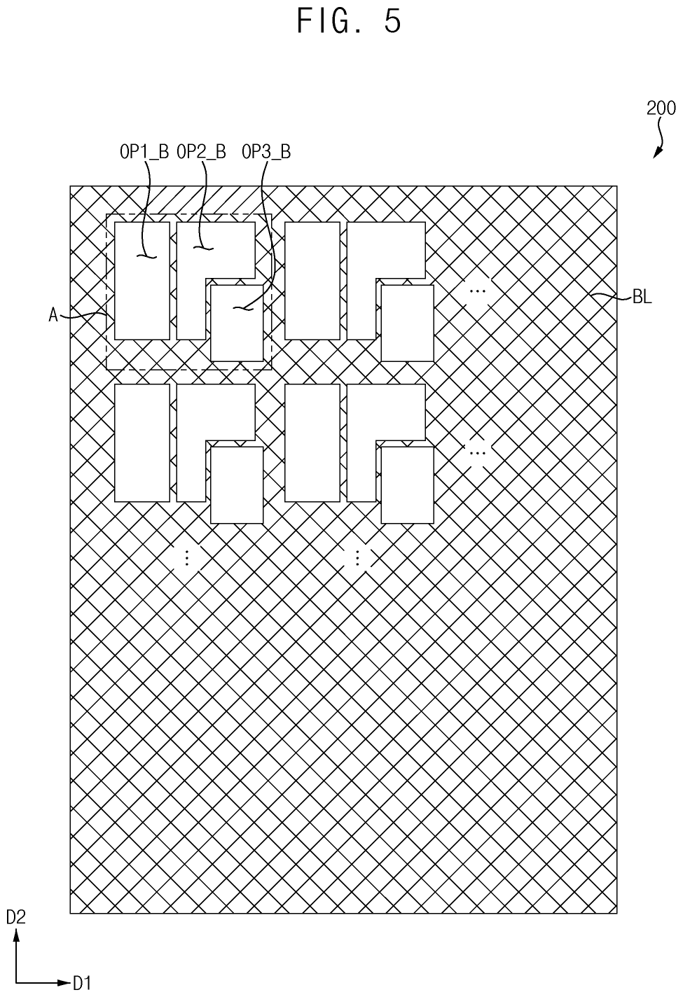

FIG. 4 is a plan view illustrating an example of a pixel defining layer of an array substrate of FIGS. 1 and 2.

Referring to FIGS. 1, 2, and 4, the array substrate 100 of the display device DD according to some embodiments of the present disclosure may include a pixel defining layer PDL.

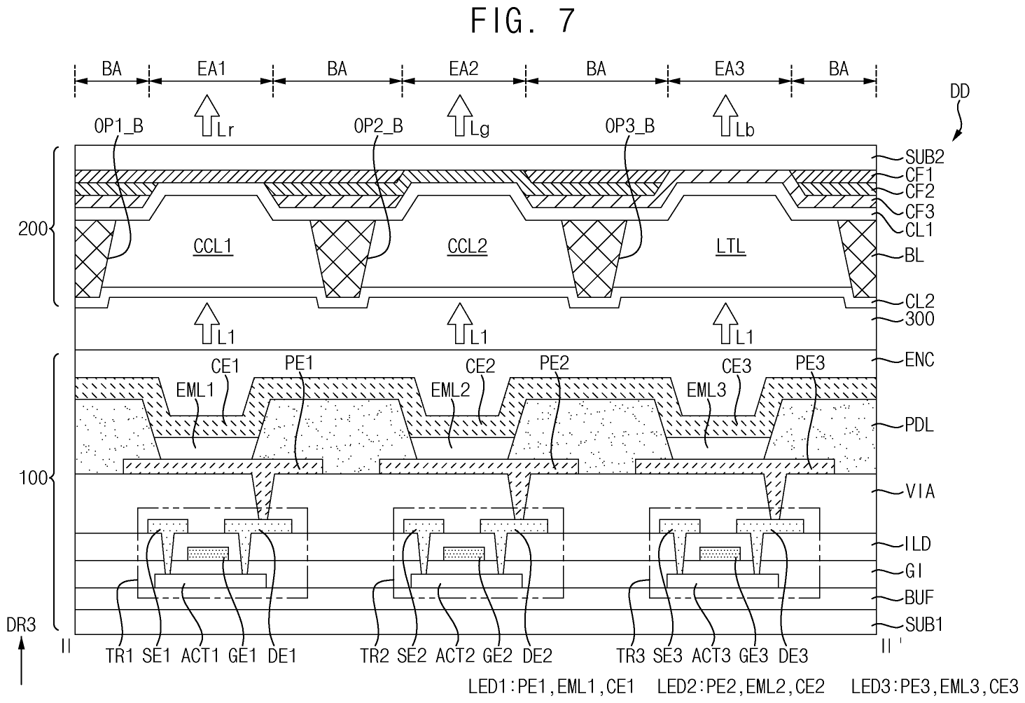

According to some embodiments, an opening exposing at least a part of an upper surface of a pixel electrode (e.g., pixel electrodes PE1, PE2, and PE3 of FIG. 7) may be defined in the pixel defining layer PDL. For example, a first opening OP1_P overlapping the first light emitting area EA1, a second opening OP2_P overlapping the second light emitting area EA2, and a third opening OP3_P overlapping the third light emitting area EA3 may be defined in the pixel defining layer PDL.

Areas of the first opening OP1_P, the second opening OP2_P, and the third opening OP3_P may be different from each other. According to some embodiments, an area of the first opening OP1_P may be greater than the area of each of the second opening OP2_P and the third opening OP3_P. In this case, the area of the second opening OP2_P may be greater than the area of the third opening OP3_P. According to some embodiments, the area of the first opening OP1_P may be the same as the area of the second opening OP2_P and may be greater than the area of the third opening OP3_P. The first opening OP1_P may have the same area as the first light emitting area EA1, the second opening OP2_P may have the same area as the second light emitting area EA2, and the third opening OP3_P may have the same area as the third light emitting area EA3. Accordingly, the first opening OP1_P may define the first light emitting area EA1, the second opening OP2_P may define the second light emitting area EA2, and the third opening OP3_P may define the third light emitting area EA3.

However, embodiments of the present disclosure are not limited thereto, and the first opening OP1_P may have an area different from the area of the first light emitting area EA1, and the second opening OP2_P may have a different area than the area of the second light emitting area EA2. area, and the third opening OP3_P may have a different area from the area of the third light emitting area EA3.

According to some embodiments, the first opening OP1_P and the third opening OP3_P may have a rectangular planar shape, and the second opening OP2_P may have an “L” shape planar shape rotated clockwise by about 90 degrees. That is, the first opening OP1_P may have the same planar shape as the first light emitting area EA1, the second opening OP2_P may have the same planar shape as the second light emitting area EA2, and the third opening OP3_P may have the same planar shape as the third light emitting area EA3.

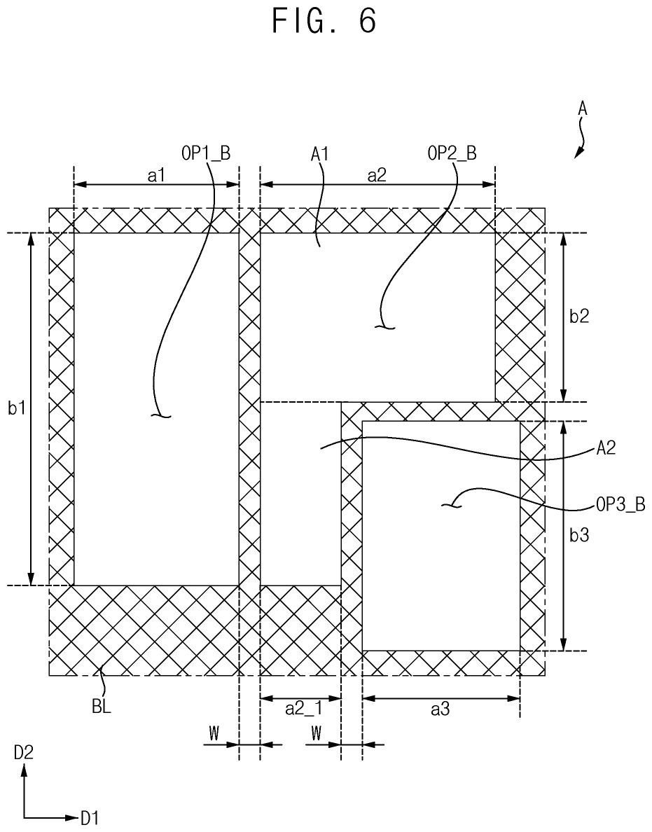

FIG. 5 is a plan view illustrating an example of a bank layer of a color conversion substrate of FIGS. 1 and 2. FIG. 6 is an enlarged plan view of the area A of FIG. 5.

Referring to FIGS. 1, 2, and 5, the color conversion substrate 200 of the display device DD according to some embodiments may include a bank layer BL.

According to some embodiments, an opening filled with a material of an optical filter may be defined in the bank layer BL. For example, a first opening OP1_B overlapping the first light emitting area EA1, a second opening OP2_B overlapping the second light emitting area EA2, and a third opening OP3_B overlapping the third light emitting area EA3 may be defined in the bank layer BL. The first opening OP1_B may be filled with a first color conversion layer (e.g., a first color conversion layer CCL1 of FIG. 7), the second opening OP2_B may be filled with a second color conversion layer (e.g., a second color conversion layer CCL2 in FIG. 7), and the third opening OP3_B may be filled with a light transmitting layer (e.g., a light transmitting layer LTL of FIG. 7).

Areas of the first opening OP1_B, the second opening OP2_B, and the third opening OP3_B may be different from each other. According to some embodiments, the area of the first opening OP1_B may be greater than the area of each of the second opening OP2_B and the third opening OP3_B. In this case, the area of the second opening OP2_B may be greater than the area of the third opening OP3_B. According to some embodiments, the area of the first opening OP1_B may be the same as the area of the second opening OP2_B and may be greater than the area of the third opening OP3_B. The first opening OP1_B may have the area different from the area of the first light emitting area EA1, the second opening OP2_B may have the area different from the area of the second light emitting area EA2, and the third opening OP3_B may have the area different from the area of the third light emitting area EA3. For example, the first opening OP1_B may have a greater area than the first light emitting area EA1, the second opening OP2_B may have a greater area than the second light emitting area EA2, and the third opening OP3_B may have a greater area than the third light emitting area EA3.

However, embodiments of the present disclosure are not limited thereto, and the first opening OP1_B may have the same area as the first light emitting area EA1, and the second opening OP2_B may have the same area as the second light emitting area EA2, and the third opening OP3_B may have the same area as the third light emitting area EA3.

According to some embodiments, each of the first opening OP1_B and the third opening OP3_B may have a rectangular planar shape, and the second opening OP2_B may have an “L” shape planar shape rotated clockwise by about 90 degrees. For example, the second opening OP2_B may have an “L” shape planar shape rotated by about 90 degrees clockwise to surround at least a part of the third opening OP3_B. That is, the first opening OP1_B may have the same planar shape as the first light emitting area EA1, the second opening OP2_B may have the same planar shape as the second light emitting area EA2, and the third opening OP3_B may have the same planar shape as the third light emitting area EA3.

1 According to some embodiments, the second opening OP2_B may have a first area A1 and a second area A2, and the second area A2 may protrude from the first area A1 in a direction opposite to the second direction D2.

According to some embodiments, the first opening OP1_B, the second opening OP2_B, and the third opening OP3_B may at least partially overlap each other in the first direction D1. In addition, the second opening OP2_B and the third opening OP3_B may at least partially overlap each other in the second direction D2. That is, the third opening OP3_B may overlap the second opening OP2_B in the first and second directions D1 and D2 and may overlap the first opening OP1_B only in the second direction D2. For example, the third opening OP3_B may partially overlap the first area A1 of the second opening OP2_B in the second direction D2 and may partially overlap the second area A2 of the second opening OP2_B in the first direction D1.

As described above, the material of the optical filter may be filled in each of the first, second, and third openings OP1_B, OP2_B, and OP3_B. According to some embodiments, an ink composition, which is a material of the optical filter, may be filled in the first, second, and third openings OP1_B, OP2_B, and OP3_B through an inkjet printing process. For example, a first ink composition may be dropped in an entire area of the first opening OP1_B, and a third ink composition may be dropped in an entire area of the third opening OP3_B. In addition, the second ink composition may be dropped in the first area A1 of the second opening OP2_B and the second ink composition dropped in the first area A1 may spread to the second area A2 of the second opening OP2_B.

In order to enable the ink composition to be accurately dropped in the first, second, and third openings OP1_B, OP2_B, and OP3_B, each of the first, second, and third openings OP1_B, OP2_B, and OP3_B may have a specific size or larger. If each of the first, second, and third openings OP1_B, OP2_B, and OP3_B is formed smaller than a specific size, the ink composition may not be accurately dropped in the first, second, and third openings OP1_B, OP2_B, and OP3_B.

For example, a length a1 of the first opening OP1_B in the first direction D1 may be about 55.7 μm, and a length b1 of the first opening OP1_B in the second direction D2 may be about 110 μm. A length a2 of the first area A1 of the second opening OP2_B in the first direction D1 may be about 87.1 μm, and a length b2 of the first area A1 of the second opening OP2_B in the second direction D2 may be about 60 μm. In addition, a length a2_1 of the second area A2 of the second opening OP2_B in the first direction D1 may be about 28 μm. A length a3 of the third opening OP3_B in the first direction D1 may be about 55.7 μm, and a length b3 of the third opening OP3_B in the second direction D2 may be about 85.5 μm. However, this is only example, and embodiments of the present disclosure are not limited thereto.

When the first, second, and third openings OP1_B, OP2_B, and OP3_B have a specific size or larger, the ink composition may be accurately (or relatively accurately) dropped in the first, second, and third openings OP1_B, OP2_B, and OP3_B. However, embodiments of the present disclosure are not limited thereto, and sizes of the first, second, and third openings OP1_B, OP2_B, and OP3_B required according to the size and resolution of the display device DD may vary.

According to some embodiments, a width W of the bank layer BL located between two adjacent openings among the first, second, and third openings OP1_B, OP2_B, and OP3_B may be about 5 μm to about 25 μm. When the width W of the bank layer BL located between two adjacent openings among the first, second, and third openings OP1_B, OP2_B, and OP3_B is less than about 5 μm or greater than about 25 μm, the color matching rate of the display device DD may decrease.

The display device DD according to some embodiments may include the bank layer BL defining the first opening OP1_B overlapping the first light emitting area EA1 that emits red light, the second opening OP2_B overlapping a second light emitting area EA2 that emits green light, and a third opening OP3_B overlapping a third light emitting area EA3 that emits blue light. Each of the at least two openings including the second opening OP2_B among the first, second, and third openings OP1_B, OP2_B, and OP3_B may have an “L” shape planar shape, and the remaining openings may have a rectangular planar shape. Accordingly, coloration of the display device DD may be relatively improved, and inkjet yield may be relatively improved in an inkjet printing process of forming the optical filter.

In addition, when the first, second, and third openings OP1_B, OP2_B, and OP3_B have a specific size or larger so that the ink composition is dropped in the first, second, and third openings OP1_B, OP2_B, and OP3_B of the bank layer BL, a sufficient tack time may be secured in the inkjet printing process of forming the optical filter.

FIG. 7 is a cross-sectional view taken along the line II-II′ of FIG. 3. Referring to FIG. 7, the display device DD according to some embodiments may include the array substrate 100, the filling layer 300, and the color conversion substrate 200. First, the array substrate 100 will be described in more detail.

The array substrate 100 may include a first substrate SUB1, a buffer layer BUF, first, second, and third transistors TR1, TR2, and TR3, a gate insulating layer GI, an interlayer insulating layer ILD, a via insulating layer VIA, a pixel defining layer PDL, first, second, and third light emitting elements LED1, LED2, and LED3, and an encapsulation layer ENC.

As described above, the display device DD may include the first light emitting area EA1, the second light emitting area EA2, the third light emitting area EA3, and the light blocking area BA. As the display device DD includes the first light emitting area EA1, the second light emitting area EA2, the third light emitting area EA3, and the light blocking area BA, components (e.g., the first substrate SUB1) included in the display device DD may also include the first light emitting area EA1, the second light emitting area EA2, the third light emitting area EA3, and the light blocking area BA.

The first substrate SUB1 may include a transparent material or an opaque material. The first substrate SUB1 may be formed of a transparent resin substrate. Examples of the transparent resin substrate include polyimide substrates and the like. In this case, the polyimide substrate may include a first organic layer, a first barrier layer, a second organic layer, and the like. Alternatively, the first substrate SUB1 may include a quartz substrate, a synthetic quartz substrate, a calcium fluoride substrate, an F-doped quartz substrate, soda-lime glass substrate, non-alkali glass substrate, and the like. These may be used alone or in combination with each other.

The buffer layer BUF may be located on the first substrate SUB1. The buffer layer BUF may prevent diffusion of metal atoms or impurities from the first substrate SUB1 to the first, second, and third transistors TR1, TR2, and TR3. In addition, the buffer layer BUF may improve the flatness of the surface of the first substrate SUB1 when the surface of the first substrate SUB1 is not uniform. For example, the buffer layer BUF may include an inorganic material such as silicon oxide, silicon nitride, silicon oxynitride, and the like. These may be used alone or in combination with each other.

First, second, and third active patterns ACT1, ACT2, and ACT3 may be located on the buffer layer BUF. Each of the first, second, and third active patterns ACT1, ACT2, and ACT3 may include a metal oxide semiconductor, an inorganic semiconductor (e.g., amorphous silicon, poly silicon), or an organic semiconductor. can Each of the first, second, and third active patterns ACT1, ACT2, and ACT3 may include a source region, a drain region, and a channel region positioned between the source region and the drain region. The first, second, and third active patterns ACT1, ACT2, and ACT3 may be formed through the same process and include the same material.

1 The metal oxide semiconductor may include a two-component compound (ABₓ), a ternary compound (ABₓC_{y}), a four-component compound (ABₓC_{y}D_{z}), and the like containing indium (In), zinc (Zn), gallium (Ga), tin (Sn), titanium (Ti), aluminum (Al), hafnium (Hf), zirconium (Zr), magnesium (Mg), and the like. For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), indium gallium zinc oxide (IGZO), and the like. These may be used alone or in combination with each other.

The gate insulating layer GI may be located on the buffer layer BUF. The gate insulating layer GI may sufficiently cover the first, second, and third active patterns ACT1, ACT2, and ACT3, and may have a substantially flat upper surface without creating a step around the first, second, and third active patterns ACT1, ACT2, and ACT3. Alternatively, the gate insulating layer GI may cover the first, second, and third active patterns ACT1, ACT2, and ACT3 and may be arranged along the profile of each of the first, second, and third active patterns ACT1, ACT2, and ACT3 to have a uniform thickness. For example, the gate insulating layer GI may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and the like. These may be used alone or in combination with each other.

First, second, and third gate electrodes GE1, GE2, and GE3 may be located on the gate insulating layer GI. The first gate electrode GE1 may overlap the channel region of the first active pattern ACT1, the second gate electrode GE2 may overlap the channel region of the second active pattern ACT2, and the third gate electrode GE3 may overlap the channel region of the third active pattern ACT3.

Each of the first, second, and third gate electrodes GE1, GE2, and GE3 may include a metal, an alloy metal nitride, a conductive metal oxide, a transparent conductive material, and the like. Examples of the metal include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of the conductive metal oxide include indium tin oxide, indium zinc oxide, and the like. In addition, examples of the metal nitride include aluminum nitride (AlNₓ), tungsten nitride (WNₓ), chromium nitride (CrNₓ), and the like. Each of these may be used alone or in combination with each other.

The first, second, and third gate electrodes GE1, GE2, and GE3 may be formed through the same process and include the same material.

The interlayer insulating layer ILD may be located on the gate insulating layer GI. The interlayer insulating layer ILD may sufficiently cover the first, second, and third gate electrodes GE1, GE2, and GE3 and may have a substantially flat upper surface without creating a step around the first, second, and third gate electrodes GE1, GE2, and GE3. Alternatively, the interlayer insulating layer ILD may cover the first, second, and third gate electrodes GE1, GE2, and GE3 and may be arranged along the profile of each of the first, second, and third gate electrodes GE1, GE2, and GE3 to have a uniform thickness. For example, the interlayer insulating layer ILD may include an inorganic material such as silicon oxide, silicon nitride, silicon carbide, silicon oxynitride, silicon oxycarbide, and the like. These may be used alone or in combination with each other.

First, second, and third source electrodes SE1, SE2, and SE3 may be located on the interlayer insulating layer ILD. The first source electrode SE1 may be connected to the source region of the first active pattern ACT1 through a contact hole penetrating the gate insulating layer GI and the interlayer insulating layer ILD. The second source electrode SE2 may be connected to the source region of the second active pattern ACT2 through a contact hole penetrating the gate insulating layer GI and the interlayer insulating layer ILD. The third source electrode SE3 may be connected to the source region of the third active pattern ACT3 through a contact hole penetrating the gate insulating layer GI and the interlayer insulating layer ILD.

First, second, and third drain electrodes DE1, DE2, and DE3 may be located on the interlayer insulating layer ILD. The first drain electrode DE1 may be connected to the drain region of the first active pattern ACT1 through a contact hole penetrating the gate insulating layer GI and the interlayer insulating layer ILD. The second drain electrode DE2 may be connected to the drain region of the second active pattern ACT2 through a contact hole penetrating the gate insulating layer GI and the interlayer insulating layer ILD. The third drain electrode DE3 may be connected to the drain region of the third active pattern ACT3 through a contact hole penetrating the gate insulating layer GI and the interlayer insulating layer ILD.

For example, each of the first, second, and third source electrodes SE1, SE2, and SE3 may include a metal, an alloy, a metal nitride, a conductive metal oxide, a transparent conductive material, and the like. These may be used alone or in combination with each other. The first, second, and third drain electrodes DE1, DE2, and DE3 may be formed through the same process as the first, second, and third source electrodes SE1, SE2, and SE3 and may include the same material as the first, second, and third source electrodes SE1, SE2, and SE3.

Accordingly, the first transistor TR1 including the first active pattern ACT1, the first gate electrode GAT1, the first source electrode SE1 and the first drain electrode DE1 may be located on the first substrate SUB1, the second transistor TR2 including the second active pattern ACT2, the second gate electrode GAT2, the second source electrode SE2, and the second drain electrode DE2 may be located on the first substrate SUB1, and the third transistor TR3 including the third active pattern ACT3, the third gate electrode GAT3, the third source electrode SE3, and the third drain electrode DE3 may be located on the first substrate SUB1.

The via insulating layer VIA may be located on the interlayer insulation layer ILD. The via insulation layer VIA may sufficiently cover the first, second, and third source electrodes SE1, SE2, and SE3 and the first, second, and third drain electrodes DE1, DE2, and DE3. The via insulating layer VIA may include an organic material. For example, the via insulating layer VIA may include phenolic resin, polyacrylates resin, polyimides rein, polyamides resin, siloxane resin, epoxy resin, and the like. These may be used alone or in combination with each other.

The first, second, and third pixel electrodes PE1, PE2, and PE3 may be located on the via insulation layer VIA. The first pixel electrode PE1 may overlap the first light emitting area EA1, the second pixel electrode PE2 may overlap the second light emitting area EA2, and the third pixel electrode PE3 may overlap the third light emitting area EA3. The first pixel electrode PE1 may be connected to the first drain electrode DE1 through a contact hole penetrating the via insulating layer VIA, the second pixel electrode PE2 may be connected to the second drain electrode DE2 through a contact hole penetrating the via insulating layer VIA, and the third pixel electrode PE3 may be connected to the third drain electrode DE3 through a contact hole penetrating the via insulation layer VIA.

For example, each of the first, second, and third pixel electrodes PE1, PE2, and PE3 may include a metal, an alloy, a metal nitride, a conductive metal oxide, a transparent conductive material, and the like. These may be used alone or in combination with each other. According to some embodiments, each of the first, second, and third pixel electrodes PE1, PE2, and PE3 may have a stacked structure including ITO/Ag/ITO. The first, second, and third pixel electrodes PE1, PE2, and PE3 may be formed through the same process and include the same material. For example, each of the first, second, and third pixel electrodes PE1, PE2, and PE3 may operate as an anode.

The pixel defining layer PDL may be located on the via insulating layer VIA. The pixel defining layer PDL may overlap the light blocking area BA. The pixel defining layer PDL may cover edges of each of the first, second, and third pixel electrodes PE1, PE2, and PE3. In addition, an opening (e.g., the first, second, and third openings OP1_P, OP2_P, and OP3_P of FIG. 4) exposing at least a part of the upper surface of each of the first, second, and third pixel electrodes PE1, PE2, and PE3 may be defined in the pixel defining layer PDL. For example, the pixel defining layer PDL may include an inorganic material or an organic material. According to some embodiments, the pixel defining layer PDL may include an organic material such as an epoxy resin, a siloxane resin, and the like. These may be used alone or in combination with each other. According to some embodiments, the pixel defining layer PDL may further include a light blocking material containing a black pigment, black dye, and the like.

The first light emitting layer EML1 may be located on the first pixel electrode PE1, the second light emitting layer EML2 may be located on the second pixel electrode PE2, and the third light emitting layer EML3 may be located on the third pixel electrode PE3. For example, the first light emitting layer EML1 may be located in a first opening (e.g., the first opening OP1_P of FIG. 4) of the pixel defining layer PDL, the second light emitting layer EML2 may be located in a second opening (e.g., the second opening OP2_P of FIG. 4) of the pixel defining layer PDL, and the third light emitting layer EML3 may be located in a third opening (e.g., the third opening OP3_P of FIG. 4) of the pixel defining layer PDL.

Each of the first, second, and third light emitting layers EML1, EML2, and EML3 may include an organic material emitting light of a color (e.g., a set or predetermined color). According to some embodiments, each of the first, second, and third light emitting layers EML1, EML2, and EML3 may include an organic material that emits blue light.

A first common electrode CE1 may be located on the first light emitting layer EML1 and the pixel defining layer PDL, a second common electrode CE2 may be located on the second light emitting layer EML2 and the pixel defining layer PDL, and a third common electrode CE3 may be located on the third light emitting layer EML3 and the pixel defining layer PDL. The first, second, and third common electrodes CE1, CE2, and CE3 may be integrally formed. For example, each of the first, second, and third common electrodes CE1, CE2, and CE3 may include a metal, an alloy, a metal nitride, a conductive metal oxide, a transparent conductive material, and the like. These may be used alone or in combination with each other. The first, second, and third common electrodes CE1, CE2, and CE3 may operate as cathodes.

Accordingly, the first light emitting element LED1 including the first pixel electrode PE1, the first light emitting layer EML1, and the first common electrode CE1 may be located in the first light emitting area EA1 on the first substrate SUB1, the second light emitting element LED2 including the second pixel electrode PE2, the second light emitting layer EML2, and the second common electrode CE2 may be located in the second light emitting area EA2 on the first substrate SUB1, and the third light emitting element LED3 including the third pixel electrode PE3, the third light emitting layer EML3, and the third common electrode CE3 may be located in the third light emitting area EA3 on the first substrate SUB1.

The first light emitting element LED1 may be electrically connected to the first transistor TR1, the second light emitting element LED2 may be electrically connected to the second transistor TR2, and the third light emitting element LED3 may be electrically connected to the third transistor TR3.

The encapsulation layer ENC may be located on the first, second, and third common electrodes CE1, CE2, and CE3. The encapsulation layer ENC may prevent impurities, moisture, air, and the like from permeating the first, second, and third light emitting elements LED1, LED2, and LED3 from the outside. The encapsulation layer ENC may include at least one inorganic layer and at least one organic layer. For example, the inorganic layer may include silicon oxide, silicon nitride, silicon oxynitride, and the like. These may be used alone or in combination with each other. The organic layer may include a polymer cured material such as polyacrylate.

Hereinafter, the color conversion substrate 200 will be described in more detail.

The color conversion substrate 200 may include a second substrate 170, first, second, and third color filters CF1, CF2, and CF3, a first capping layer CL1, the bank layer BL, the first and second color conversion layers CCL1 and CCL2, the light transmission layer LTL, and a second capping layer CL2.

The second substrate 170 may transmit light emitted from the first, second, and third light emitting elements LED1, LED2, and LED3. For example, the second substrate 170 may be formed of a transparent resin substrate. The second substrate 170 may include an insulating material such as glass or plastic. Alternatively, the second substrate 170 may include an organic polymer material such as polycarbonate (PC), polyethylene (PE), polypropylene (PP), and the like. These may be used alone or in combination with each other.

A color filter layer may be located under the second substrate 170. The color filter layer may selectively transmit light having a specific wavelength. The color filter layer may include the first color filter CF1, the second color filter CF2, and the third color filter CF3.

The first color filter CF1 may selectively transmit light of a first color (e.g., red light Lr). The first color filter CF1 may overlap the first light emitting area EA1 and the light blocking area BA. In this case, the first color filter CF1 may not overlap the second and third light emitting areas EA2 and EA3.

The second color filter CF2 may selectively transmit second color light (e.g., green light Lg). The second color filter CF2 may overlap the second light emitting area EA2 and the light blocking area BA. In this case, the second color filter CF2 may not overlap the first and third light emitting areas EA1 and EA3.

The third color filter CF3 may selectively transmit third color light (e.g., blue light Lb). The third color filter CF3 may overlap the third light emitting area EA3 and the light blocking area BA. In this case, the third color filter CF3 may not overlap the first and second light emitting areas EA1 and EA2.

A light blocking layer may be located under the second substrate 170. The light blocking layer may overlap the light blocking area BA. Light emitted from the first, second, and third light emitting elements LED1, LED2, and LED3 may transmit only a partial area of the color conversion substrate 200. That is, the light emitted from the first, second, and third light emitting elements LED1, LED2, and LED3 may transmit only an area of the color conversion substrate 200 overlapping the first, second, and third light emitting areas EA1, EA2, and EA3 and may not transmit an area of the color conversion substrate 200 overlapping the light blocking area BA. According to some embodiments, the light blocking layer may be formed by overlapping and stacking the first, second, and third color filters CF1, CF2, and CF3.

According to some embodiments, the light blocking layer may include a light blocking material. For example, the light blocking material may have a specific color. The first capping layer CL1 may be located under the color filter layer. The first capping layer CL1 may cover the color filter layer. The first capping layer CL1 may block external impurities to prevent contamination of the color filter layer. For example, the first capping layer CL1 may include an inorganic material such as silicon oxide, silicon nitride, silicon oxynitride, and the like. These may be used alone or in combination with each other.

The bank layer BL may be located under the first capping layer CL1. The bank layer BL may overlap the light blocking area BA. In the process of forming the first color conversion layer CCL1, the second color conversion layer CCL2, and the light transmission layer LTL, a space capable of accommodating an ink composition may be formed in the bank layer BL. According to some embodiments, the first opening OP1_B overlapping the first light emitting area EA1, the second opening OP2_B overlapping the second light emitting area EA2, and the third opening OP3_B overlapping the third light emitting area EA3 may be defined in the bank layer BL. The first, second, and third openings OP1_B, OP2_B, and OP3_B may accommodate the ink composition.

For example, the bank layer BL may include an organic material such as polyimide and the like. Alternatively, the bank layer BL may include an organic material containing a light blocking material. In this case, the bank layer BL may have a black color.

The optical filter may be located under the first capping layer CL1. For example, the optical filter may include the first color conversion layer CCL1, the second color conversion layer CCL2, and the light transmission layer LTL. The first color conversion layer CCL1 may overlap the first light emitting area EA1, the second color conversion layer CCL2 may overlap the second light emitting area EA2, and the light transmission layer LTL may overlap the third light emitting area EA3.

According to some embodiments, the first color conversion layer CCL1 may be arranged to fill the first opening OP1_B of the bank layer BL, the second color conversion layer CCL2 may be arranged to fill the second opening OP2_B of the bank layer BL, and the light transmission layer LTL may be arranged to fill the third opening OP3_B of the bank layer BL. Accordingly, the first color conversion layer CCL1 may have the same planar shape as the first opening OP1_B, the second color conversion layer CCL2 may have the same planar shape as the second opening OP2_B, and the light transmission layer LTL may have the same planar shape as the third opening OP3_B.

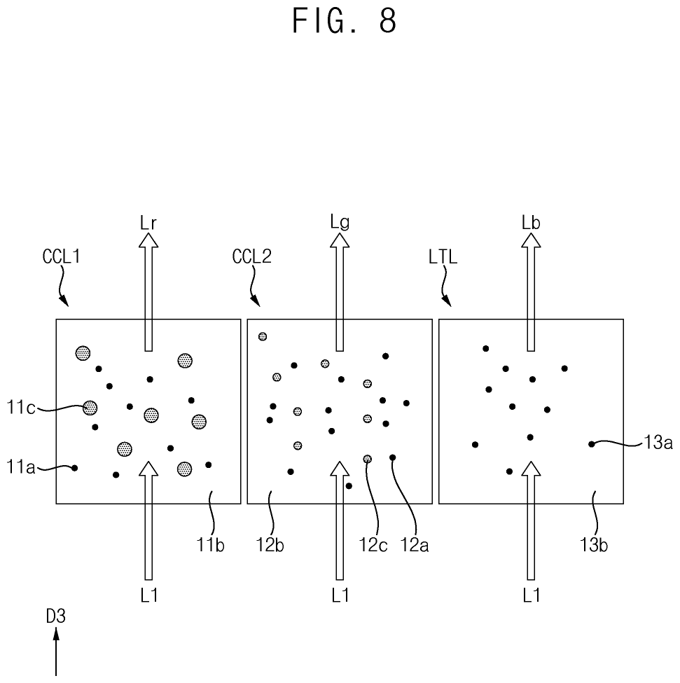

FIG. 8 is a cross-sectional view illustrating a first color conversion layer, a second color conversion layer, and a light transmission layer of the display device of FIG. 7.

Referring to FIG. 8, the first color conversion layer CCL1 may include first quantum dots 11c excited by the light L1 emitted from the first light emitting element LED1 to emit light of a first color (e.g., the red light Lr). In addition, the first color conversion layer CCL1 may further include a first photosensitive polymer 11b in which first scattering particles 11a are dispersed.

The second color conversion layer CCL2 may include second quantum dots 12c excited by the light L1 emitted from the second light emitting element LED2 to emit light of a second color (e.g., the green light Lg). In addition, the second color conversion layer CCL2 may further include a second photosensitive polymer 12b in which second scattering particles 12a are dispersed.

The light transmission layer LTL may emit blue light Lb by transmitting the light L1 emitted from the third light emitting element LED3. In addition, the light transmission layer LTL may include a third photosensitive polymer 13b in which third scattering particles 13a are dispersed.

For example, each of the first, second, and third photosensitive polymers 11b, 12b, and 13b may include a light transmitting organic material such as a silicone resin, an epoxy resin, and the like. In addition, the first, second, and third photosensitive polymers 11b, 12b, and 13b may include the same material as each other.

For example, the first, second, and third scattering particles 11a, 12a, and 13a may scatter and emit light emitted from the first, second, and third light emitting elements LED1, LED2, and LED3. In addition, the first, second, and third scattering particles 11a, 12a, and 13a may include the same material as each other.

Accordingly, the first light emitting area EA1 may emit red light Lr, the second light emitting area EA2 may emit green light Lg, and the third light emitting area EA3 may emit blue light Lb.

Referring back to FIG. 7, the second capping layer CL2 may be located on the bank layer BL and the optical filter. The second capping layer CL2 may be arranged along the profile of the bank layer BL and the optical filter. The second capping layer CL2 may play a role of preventing moisture permeation to prevent or reduce deterioration of the optical filter. For example, the second capping layer CL2 may include an inorganic material such as silicon oxide, silicon nitride, silicon oxynitride, and the like. These may be used alone or in combination with each other.

However, although the display device DD of the present disclosure is limited to an organic light emitting display device (OLED), the configuration of embodiments according to the present disclosure is not limited thereto. In other embodiments, the display device DD may include a liquid crystal display device (LCD), a field emission display device (FED), a plasma display device (PDP), or an electrophoretic display device (EPD).

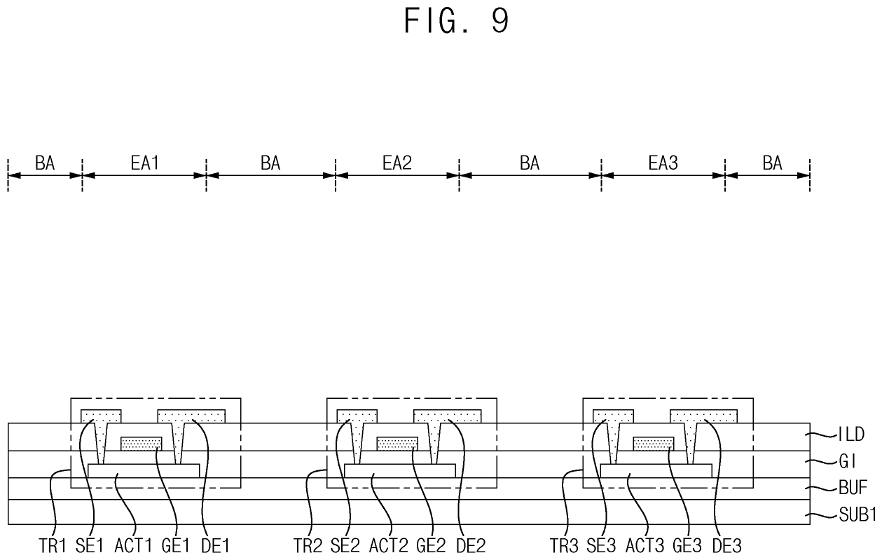

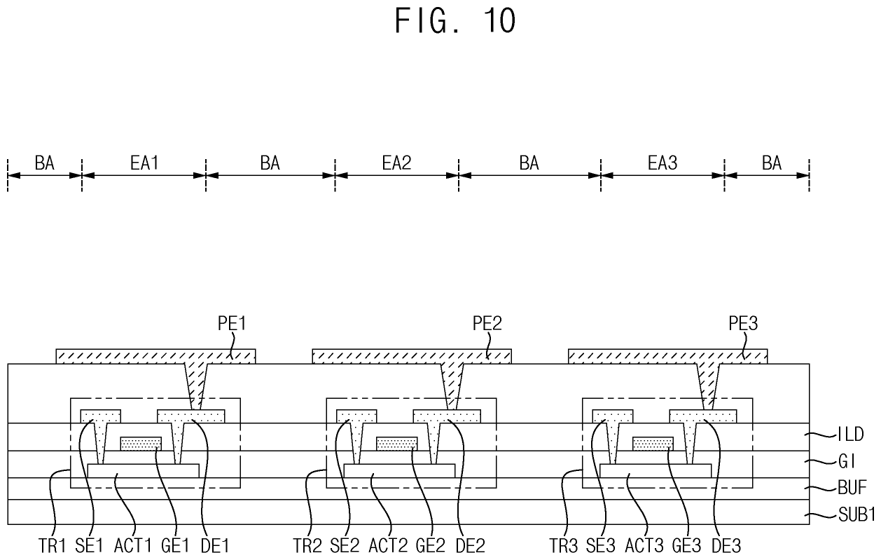

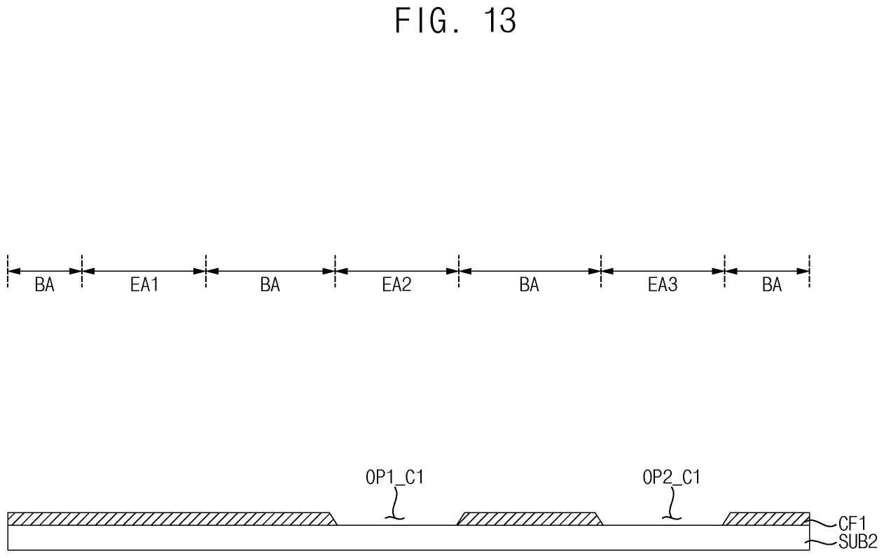

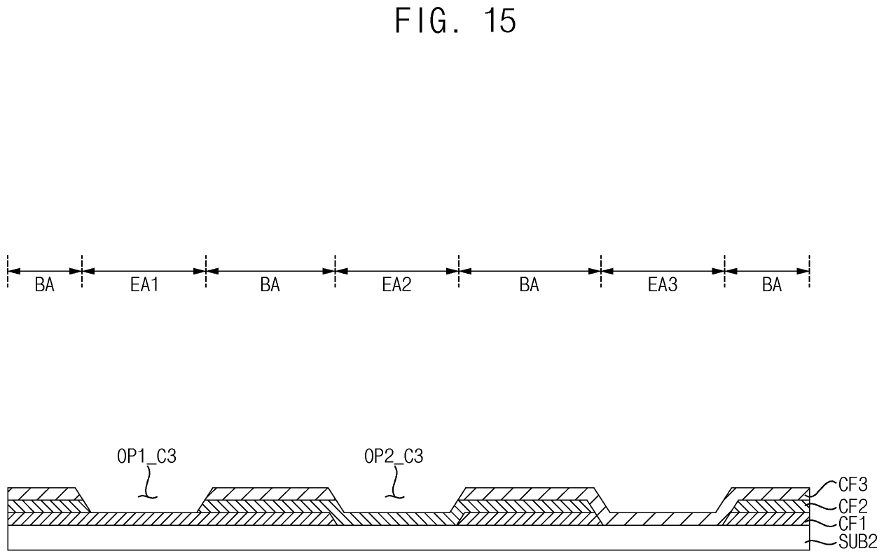

FIGS. 9, 10, 11, 12, 13, 14, 15, 16, 17 18, 19, and 20 are cross-sectional views for explaining a method of manufacturing the display device of FIG. 7. For example, FIGS. 9, 10, 11, and 12 are cross-sectional views for explaining a method of manufacturing the array substrate 100 of the display device DD of FIG. 7. FIGS. 13, 14, 15, 16, 17, 18, 19, and 20 are cross-sectional views for explaining a method of manufacturing the color conversion substrate 200 of the display device DD of FIG. 7.

Referring to FIG. 9, the buffer layer BUF1, the first, second, and third transistors TR1, TR2, and TR3, the gate insulating layer GI, and the interlayer insulating layer ILD may be sequentially formed on the first substrate SUB1.

The first transistor TR1 may include the first active pattern ACT1 formed on the buffer layer BUF, the first gate electrode GE1 formed on the gate insulating layer GI, and the first source electrode SE1 and the first drain electrode DE1 formed on the interlayer insulating layer ILD.

The second transistor TR2 may include the second active pattern ACT2 formed on the buffer layer BUF, the second gate electrode GE2 formed on the gate insulating layer GI, and the second source electrode SE2 and the second drain electrode DE2 formed on the interlayer insulating layer ILD.

The third transistor TR3 may include the third active pattern ACT3 formed on the buffer layer BUF, the third gate electrode GE3 formed on the gate insulating layer GI, and the third source electrode SE3 and the third drain electrode DE3 formed on the interlayer insulating layer ILD.

Referring to FIG. 10, the via insulating layer VIA may be formed on the interlayer insulation layer ILD. The via insulating layer VIA may sufficiently cover the first, second, and third source electrodes SE1, SE2, and SE3 and the first, second, and third drain electrodes DE1, DE2, and DE3. For example, the via insulating layer VIA may be formed using an organic material.

The first, second, and third pixel electrodes PE1, PE2, and PE3 may be formed on the via insulating layer VIA. The first pixel electrode PE1 may be connected to the first drain electrode DE1 through a contact hole formed by removing a part of the via insulating layer VIA, the second pixel electrode PE2 may be connected to the second drain electrode DE2 through a contact hole formed by a part of the via insulating layer VIA, and the third pixel electrode PE3 may be connected to the third drain electrode DE3 through a contact hole formed by a part of the via insulating layer VIA.

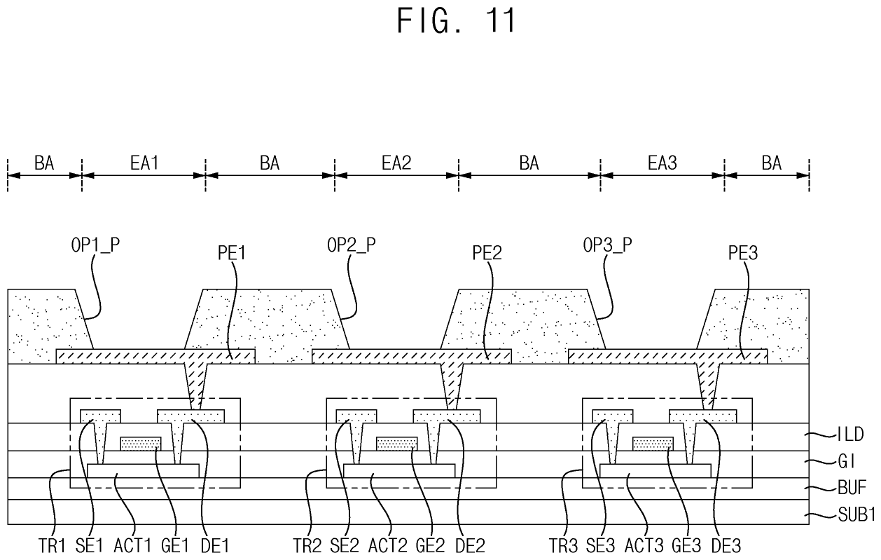

Referring to FIG. 11, the pixel defining layer PDL may be formed on the via insulating layer VIA and the first, second, and third pixel electrodes PE1, PE2, and PE3. For example, after a preliminary pixel defining layer is entirely formed on the via insulating layer VIA and the first, second, and third pixel electrodes PE1, PE2, and PE3, a part of the preliminary pixel defining layer is removed through an etching process to form the pixel definition layer PDL. Accordingly, in the pixel defining layer PDL, the first opening OP1_P exposing at least a part of the upper surface of the first pixel electrode PE1, the second opening OP2_P exposing at least a part of the upper surface of the second pixel electrode PE2, and third opening OP3_P exposing at least a part of the upper surface of the third pixel electrode PE3 may be formed. For example, the pixel defining layer PDL may be formed using an organic material.

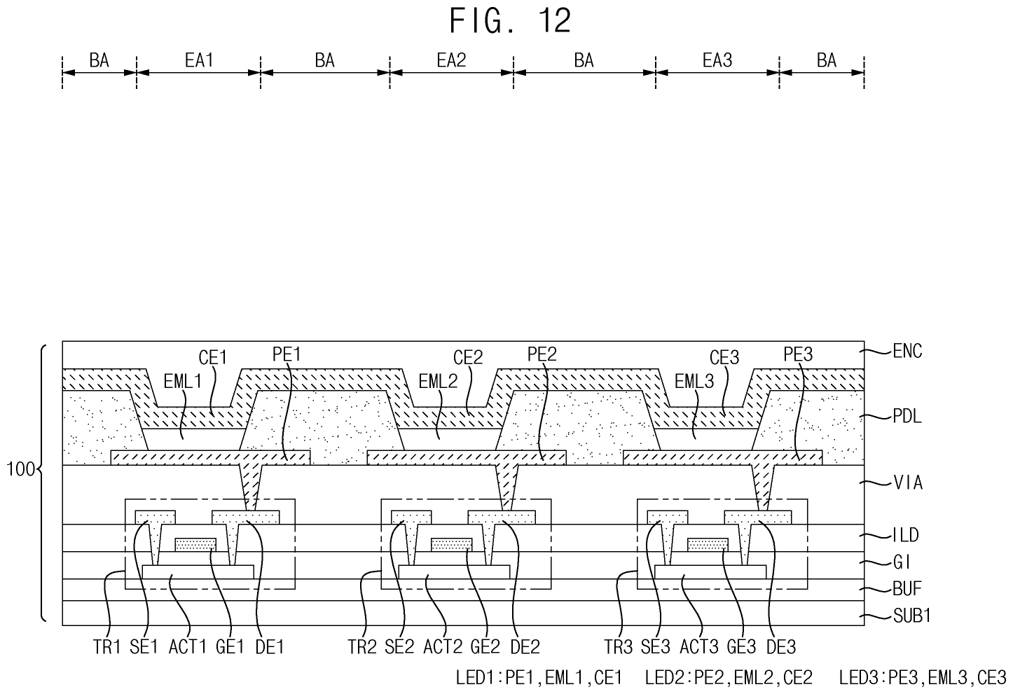

Referring to FIGS. 11 and 12, the first light emitting layer EML1 may be formed in the first opening OP1_P, the second light emitting layer EML2 may be formed in the second opening OP2_P, and the third light emitting layer EML3 may be formed in the third opening OP3_P. For example, each of the first, second, and third light emitting layers EML1, EML2, and EML3 may be formed using an organic material that emits light (e.g., a set or predetermined light).

The first, second, and third common electrodes CE1, CE2, and CE3 may be formed on the pixel defining layer PDL and the first, second, and third light emitting layers EML1, EML2, and EML3. The first, second, and third common electrodes CE1, CE2, and CE3 may be integrally formed. That is, the first, second, and third common electrodes CE1, CE2, and CE3 may be entirely formed in the first light emitting area EA1, the second light emitting area EA2, the third light emitting area EA3, and the light blocking area BA.

The encapsulation layer ENC may be formed on the first, second, and third common electrodes CE1, CE2, and CE3. The encapsulation layer ENC may include at least one inorganic encapsulation layer and at least one organic encapsulation layer.

Accordingly, the array substrate 100 illustrated in FIG. 7 may be manufactured.

Referring to FIG. 13, the first color filter CF1 may be formed on the second substrate SUB2. The first color filter CF1 may be a red color filter that transmits red light. For example, the first color filter CF1 may be formed from a red pigment and/or a color filter composition including the red pigment.

According to some embodiments, a (1-1)th opening OP1_C1 overlapping the second light emitting area EA2 and a (2-1)th opening OP2_C1 overlapping the third light emitting area EA3 may be formed (or defined) in the first color filter CF1.

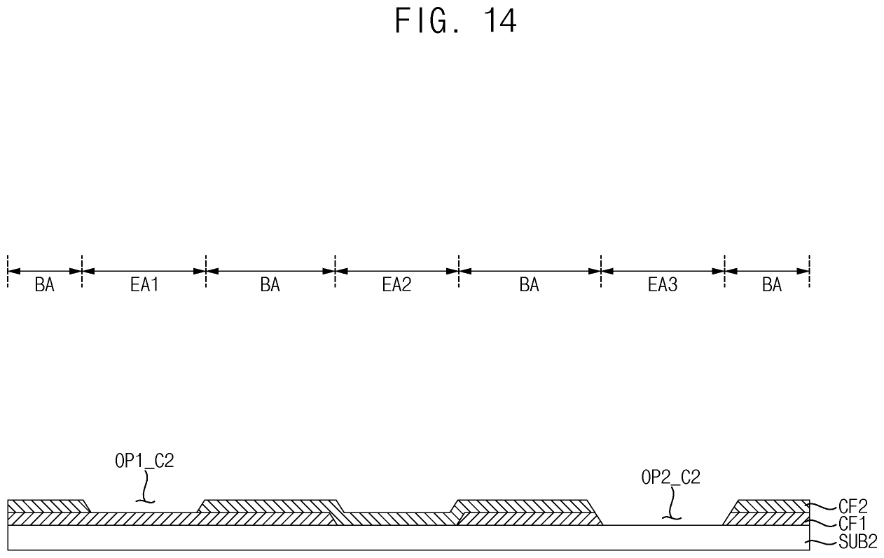

Referring to FIGS. 13 and 14, the second color filter CF2 may be formed on the second substrate SUB2 and the first color filter CF1. The second color filter CF2 may be a green color filter that transmits green light. For example, the second color filter CF2 may be formed from a green pigment and/or a color filter composition including the green pigment.

According to some embodiments, a (1-2)th opening OP1_C1 overlapping the first light emitting area EA1 and a (2-2)th opening OP2_C2 overlapping the third light emitting area EA3 may be formed (or defined) in the second color filter CF2. The (1-2)th opening OP2_C1 of the second color filter CF2 may expos a part of the upper surface of the first color filter CF1 in the first light emitting area EA1, and the (2-2)th opening OP2_C2 of the second color filter CF2 may be connected to the (2-1)th opening OP2_C1 of the first color filter CF1.

Referring to FIGS. 13, 14 and 15, the third color filter CF3 may be formed on the second color filter CF2 and the second substrate 170. The third color filter CR3 may be a blue color filter that transmits blue light. The third color filter CF3 may be formed from a blue pigment and/or a color filter composition including the blue pigment.

According to some embodiments, a (1-3)th opening OP1_C3 overlapping the first light emitting area EA1 and a (2-3)th opening OP2_C3 overlapping the second light emitting area EA2 may be formed (or defined) in the third color filter CF3. The (1-3)th openings OP1_C3 of the third color filter CF3 may be connected to the (1-2)th openings OP1_C2 of the second color filter CF2, and the (2-3)th opening OP2_C3 of the third color filter CF3 may expose a part of the upper surface of the second color filter CF2 in the second light emitting area EA2.

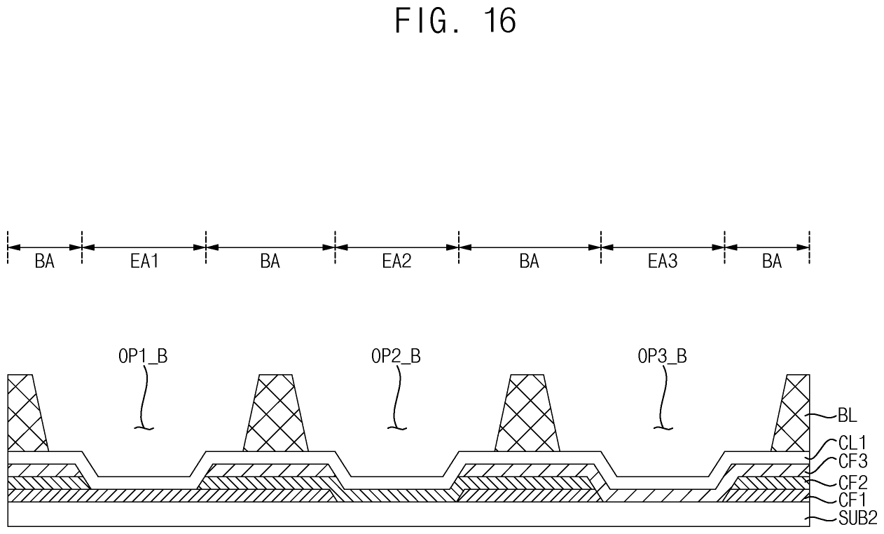

Referring to FIG. 16, the first capping layer CL1 may be formed on the first, second, and third color filters CF1, CF2, and CF3. For example, the first capping layer CL1 may be formed using an inorganic material.

The bank layer BL may be formed on the first capping layer CL1. The first opening OP1_B overlapping the first light emitting area EA1, the second opening OP2_B overlapping the second light emitting area EA2, and the third opening OP3_B overlapping the third light emitting area EA3 may be formed in the bank layer BL. Each of the first, second, and third openings OP1_B, OP2_B, and OP3_B may expose at least a part of the upper surface of the first capping layer CL1. For example, the bank layer BL may be formed using an organic material.

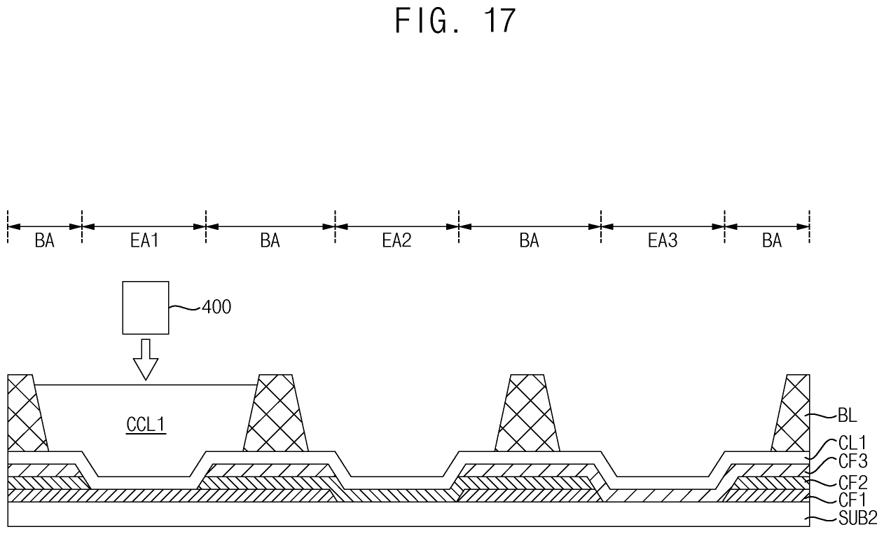

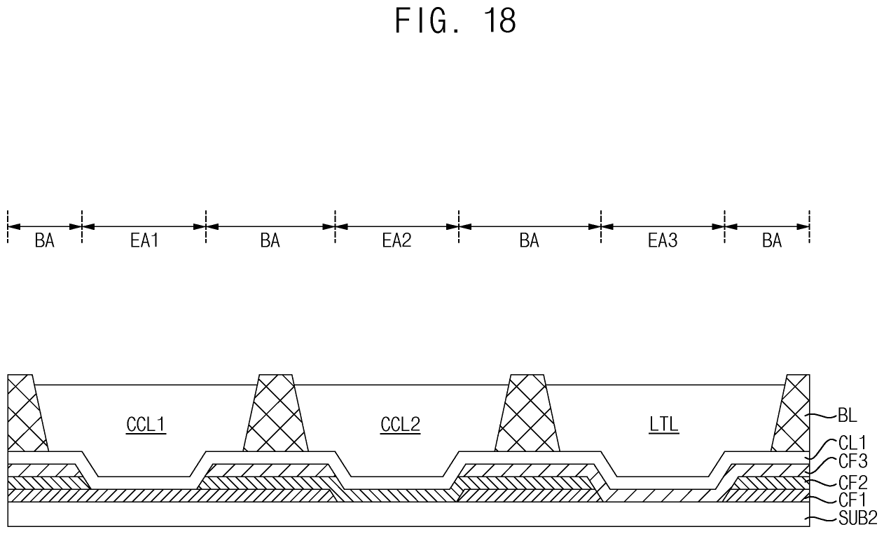

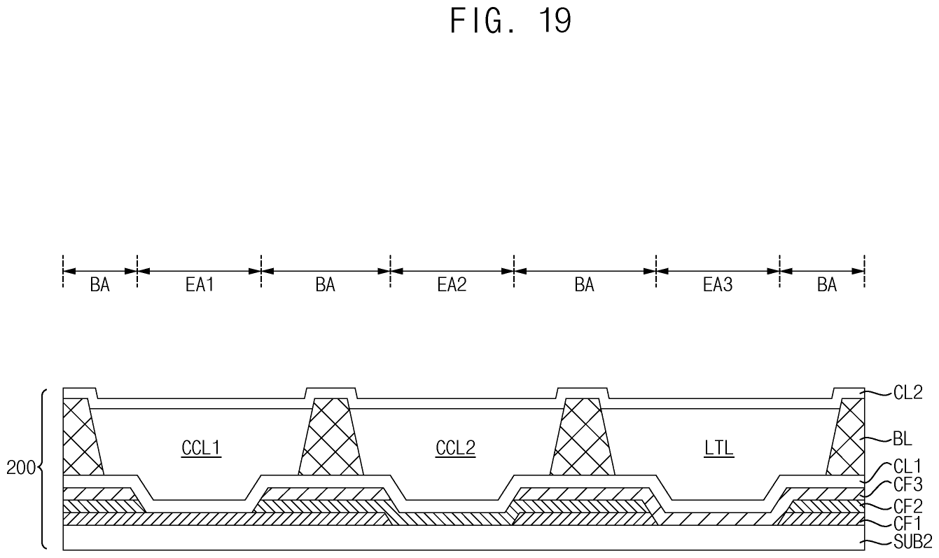

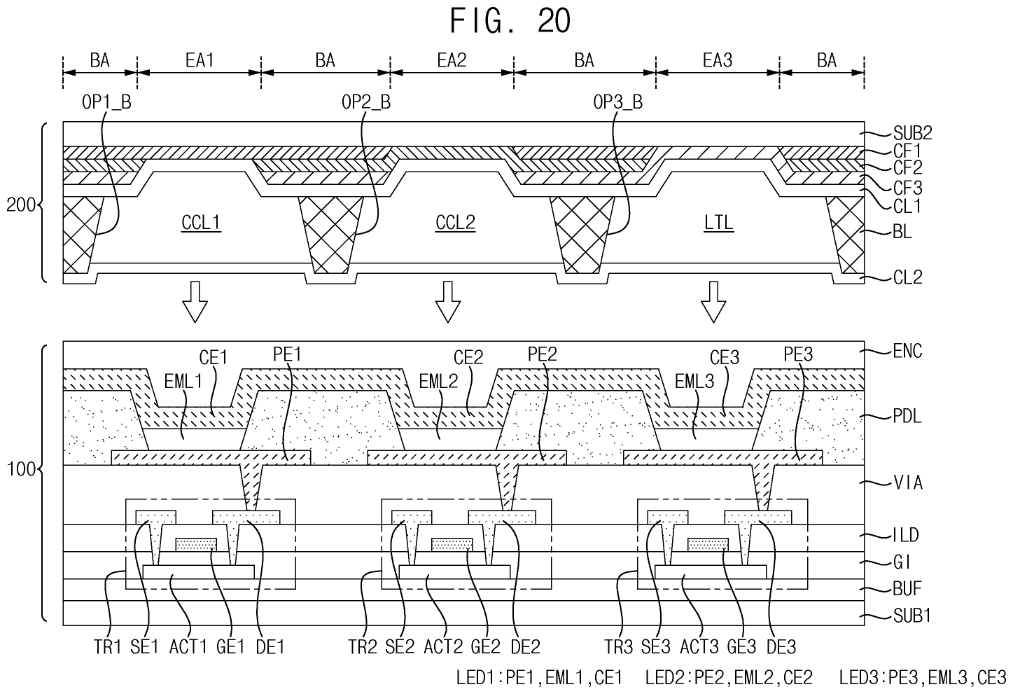

Referring to FIGS. 17 and 18, an inkjet apparatus 400 may drop a first ink composition onto the first opening OP1_B in a scanning manner. Here, the first ink composition may be a material forming the first color conversion layer CCL1.

The first color conversion layer CCL1 may be formed by repeatedly dropping the first ink composition in the first opening OP1_B by the inkjet apparatus 400 in a scanning manner. For example, three drops of the first ink composition may be dropped in the first opening OP1_B per scan. However, embodiments of the present disclosure are not limited thereto.

Then, after the inkjet apparatus 400 moves onto the second opening OP2_B, the second color conversion layer CCL2 may be formed by repeatedly dropping the second ink composition in the second opening OP2_B. For example, three drops of the second ink composition may be dropped in the second opening OP2_B per scan. However, embodiments of the present disclosure are not limited thereto.

In addition, after the inkjet apparatus 400 moves onto the third opening OP3_B, the third color conversion layer CCL3 may be formed by repeatedly dropping the third ink composition in the third opening OP3_B. For example, two drops of the third ink composition may be dropped in the third opening OP3_B per scan. However, embodiments of the present disclosure are not limited thereto.

Here, the second ink composition may be a material forming the second color conversion layer CCL2, and the third ink composition may be a material forming the light transmission layer LTL.

Referring to FIG. 19, the second capping layer CL2 may be formed on the bank layer BL, the first color conversion layer CCL1, the second color conversion layer CCL2, and the light transmission layer LTL. The second capping layer CL2 may cover the bank layer BL, the first color conversion layer CCL1, the second color conversion layer CCL2, and the light transmission layer LTL. For example, the second capping layer CL2 may be formed using an inorganic material.

Accordingly, the color conversion substrate 200 illustrated in FIG. 7 may be manufactured.

Referring to FIGS. 7 and 20, the array substrate 100 and the color conversion substrate 200 may be coupled. For example, the array substrate 100 and the color conversion substrate 200 may be coupled through a sealing portion (e.g., the sealing portion 305 of FIG. 2). In this case, an empty space between the array substrate 100 and the color conversion substrate 200 may be filled with the filling layer 300. As the array substrate 100 and the color conversion substrate 200 are combined, the display device DD illustrated in FIG. 7 may be manufactured.

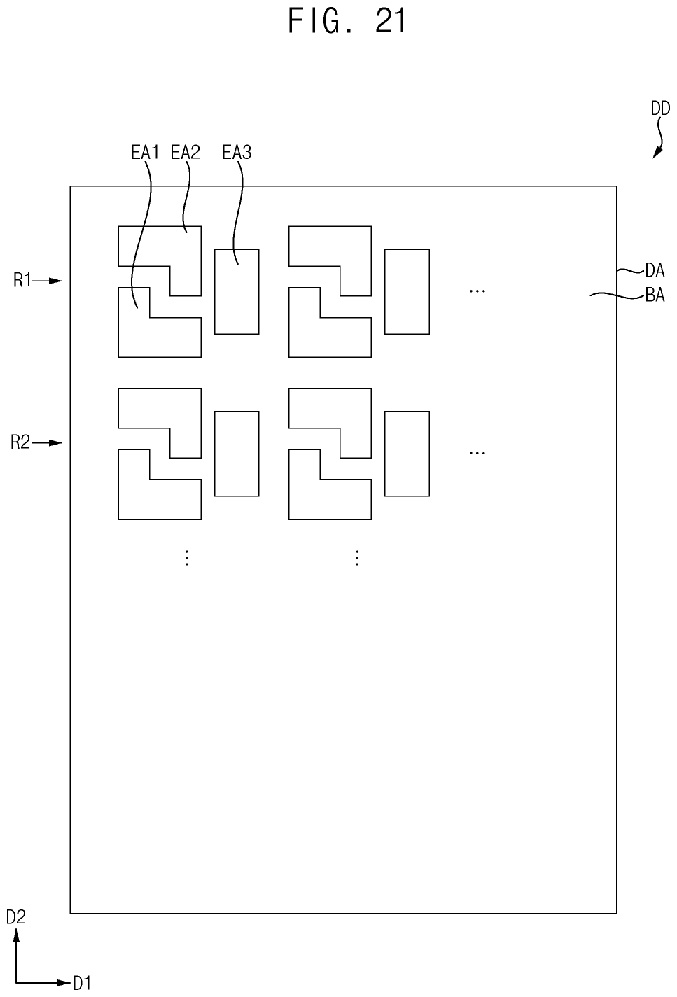

FIG. 21 is a plan view illustrating another example of the display device of FIGS. 1 and 2.

Referring to FIG. 21, a display area DA of the display device DD may include a first light emitting area EA1, a second light emitting area EA2, a third light emitting area EA3, and a light blocking area BA. Hereinafter, some descriptions overlapping those of the display device DD described with reference to FIG. 3 may be omitted or simplified.

The first light emitting area EA1, the second light emitting area EA2, and the third light emitting area EA3 may be repeatedly arranged along the first direction D1 and the second direction D2. According to some embodiments, the first and second light emitting areas EA1 and EA2 may be repeatedly arranged in odd columns along the second direction D2, and the third light emitting areas EA3 may be repeatedly arranged in even rows in the second direction D2.

For example, the first, second, and third light emitting areas EA1, EA2, and EA3 may be repeatedly arranged along the first direction D1 in a first row R1. Similarly, the first, second, and third light emitting areas EA1, EA2, and EA3 may be repeatedly arranged along the first direction D1 in a second row R2 adjacent to the first row R1. Meanwhile, the first and second light emitting areas EA1 and EA2 may be repeatedly arranged along the second direction D2 in a first column, and the third light emitting area EA3 may be repeatedly arranged along the second direction D2 in a second column adjacent to the first column. The arrangement of the light emitting areas may be repeated up to a row (e.g., a set or predetermined row) and a column (e.g., a set or predetermined column).

Areas of the first light emitting area EA1, the second light emitting area EA2, and the third light emitting area EA3 may be different from each other. According to some embodiments, the area of the first light emitting area EA1 that emits red light may be greater than the area of each of the second light emitting area EA2 that emits green light and the third light emitting area EA3 that emits blue light. In this case, the area of the second light emitting area EA2 may be greater than the area of the third light emitting area EA3. According to some embodiments, the area of the first light emitting area EA1 that emits red light may be the same as the area of the second light emitting area EA2 that emits green light and may be greater than the area of the third light emitting area EA3 that emits blue light.

According to some embodiments, the third light emitting area EA3 may have a rectangular planar shape, the first light emitting area EA1 may have an “L” shape planar shape, and the second light emitting area EA2 may have an “L” shape planar shape rotated by about 180 degrees in a counterclockwise or clockwise direction. For example, the first light emitting area EA1 may have a planar shape surrounding at least a part of the second light emitting area EA2, and the second light emitting area EA2 may have a planar shape surrounding at least a part of the first light emitting area EA1.

According to some embodiments, the first light emitting area EA1, the second light emitting area EA2, and the third light emitting area EA3 may at least partially overlap each other in the first direction D1. In addition, the first light emitting area EA1 and the second light emitting area EA2 may overlap each other in the second direction D2. That is, the third light emitting area EA3 may overlap the first and second light emitting areas EA1 and EA2 in the first direction D1 and may not overlap in the second direction D2.

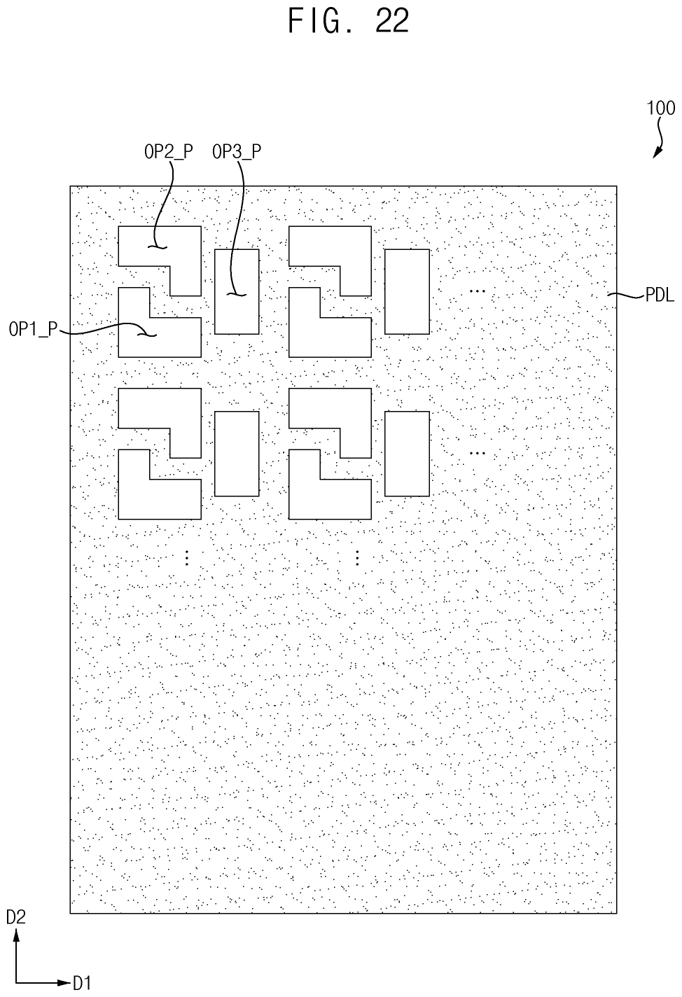

FIG. 22 is a plan view illustrating another example of a pixel defining layer of an array substrate of FIGS. 1 and 2.

Referring to FIGS. 1, 2, and 22, the array substrate 100 of the display device DD may include a pixel defining layer PDL. Hereinafter, some descriptions overlapping those of the array substrate 100 described with reference to FIG. 4 may be omitted or simplified.

According to some embodiments, a first opening OP1_P overlapping the first light emitting area EA1, a second opening OP2_P overlapping the second light emitting area EA2, and a third opening OP3_P overlapping the third light emitting area EA3 may be defined in the pixel defining layer PDL.

According to some embodiments, an area of the first opening OP1_P may be greater than the area of each of the second opening OP2_P and the third opening OP3_P. In this case, the area of the second opening OP2_P may be greater than the area of the third opening OP3_P. According to some embodiments, the area of the first opening OP1_P may be the same as the area of the second opening OP2_P and may be greater than the area of the third opening OP3_P. The first opening OP1_P may have the same area as the first light emitting area EA1, the second opening OP2_P may have the same area as the second light emitting area EA2, and the third opening OP3_P may have the same area as the third light emitting area EA3. Accordingly, the first opening OP1_P may define the first light emitting area EA1, the second opening OP2_P may define the second light emitting area EA2, and the third opening OP3_P may define the third light emitting area EA3.

However, embodiments of the present disclosure are not limited thereto, and the first opening OP1_P may have an area different from the area of the first light emitting area EA1, and the second opening OP2_P may have a different area than the area of the second light emitting area EA2. area, and the third opening OP3_P may have a different area from the area of the third light emitting area EA3.

According to some embodiments, the third opening OP3_P may have a rectangular planar shape, the first opening OP1_P may have an “L” shape planar shape, and the second opening OP2_P may have an “L” shape planar shape rotated by about 180 degrees in a counterclockwise or clockwise direction. That is, the first opening OP1_P may have the same planar shape as the first light emitting area EA1, the second opening OP2_P may have the same planar shape as the second light emitting area EA2, and the third opening OP3_P may have the same planar shape as the third light emitting area EA3.

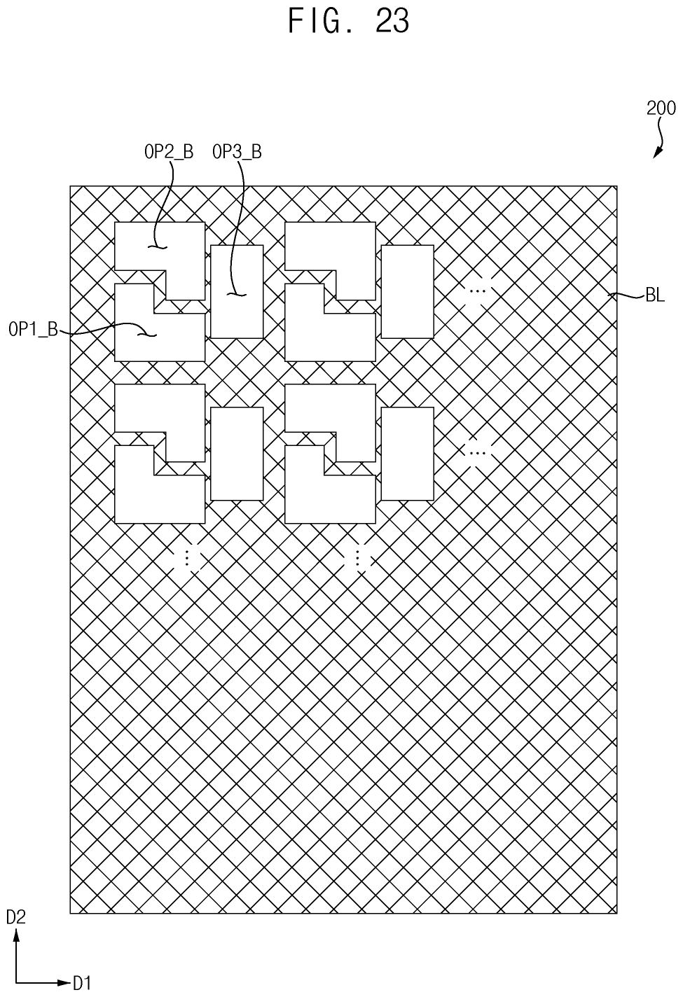

FIG. 23 is a plan view illustrating another example of a bank layer of a color conversion substrate of FIGS. 1 and 2.

Referring to FIGS. 1, 2, and 23, the color conversion substrate 200 of the display device DD may include a bank layer BL. Hereinafter, some descriptions overlapping with those of the color conversion substrate 200 described with reference to FIGS. 5 and 6 may be omitted or simplified.

According to some embodiments, a first opening OP1_B overlapping the first light emitting area EA1, a second opening OP2_B overlapping the second light emitting area EA2, and a third opening OP3_B overlapping the third light emitting area EA3 may be defined in the bank layer BL.

According to some embodiments, the area of the first opening OP1_B may be greater than the area each of the second opening OP2_B and the third opening OP3_B. In this case, the area of the second opening OP2_B may be greater than the area of the third opening OP3_B. According to some embodiments, the area of the first opening OP1_B may be the same as the area of the second opening OP2_B and may be greater than the area of the third opening OP3_B. The first opening OP1_B may have the area different from the area of the first light emitting area EA1, the second opening OP2_B may have the area different from the area of the second light emitting area EA2, and the third opening OP3_B may have the area different from the area of the third light emitting area EA3. For example, the first opening OP1_B may have a greater area than the first light emitting area EA1, the second opening OP2_B may have a greater area than the second light emitting area EA2, and the third opening OP3_B may have a greater area than the third light emitting area EA3.

However, embodiments of the present disclosure are not limited thereto, and the first opening OP1_B may have the same area as the first light emitting area EA1, and the second opening OP2_B may have the same area as the second light emitting area EA2, and the third opening OP3_B may have the same area as the third light emitting area EA3.

According to some embodiments, the third opening OP3_B may have a rectangular planar shape, the first opening OP1_B may have an “L” shape planar shape, and the second opening OP2_B may have an “L” shape planar shape rotated by about 180 degrees in a counterclockwise or clockwise direction. For example, For example, the first opening OP1_B may have a planar shape surrounding at least a part of the second opening OP2_B, and the second opening OP2_B may have a planar shape surrounding at least a part of the first opening OP1_B. That is, the first opening OP1_B may have the same planar shape as the first light emitting area EA1, the second opening OP2_B may have the same planar shape as the second light emitting area EA2, and the third opening OP3_B may have the same planar shape as the third light emitting area EA3.

According to some embodiments, the first opening OP1_B, the second opening OP2_B, and the third opening OP3_B may at least partially overlap each other in the first direction D1. In addition, the first opening OP1_B and the second opening OP2_B may overlap each other in the second direction D2. That is, the third opening OP3_B may overlap the first and second openings OP1_B and OP2_B in the first direction D1 and may not overlap in the second direction D2.

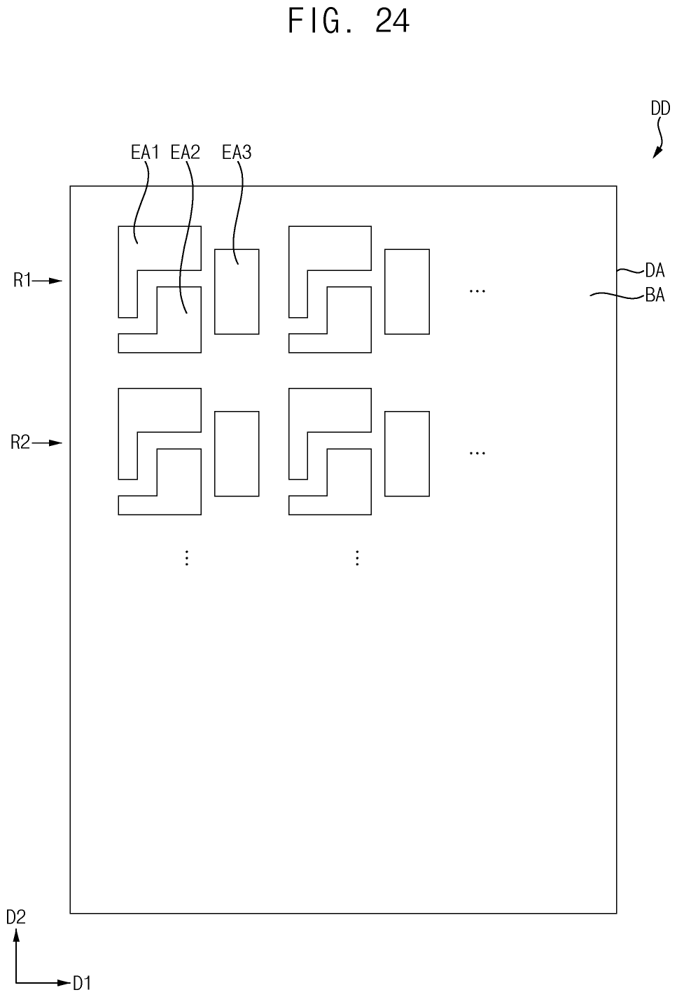

FIG. 24 is a plan view illustrating another example of the display device of FIGS. 1 and 2.

Referring to FIGS. 1, 2 and 24, a display area DA of the display device DD may include a first light emitting area EA1, a second light emitting area EA2, a third light emitting area EA3, and a light blocking area BA. Hereinafter, some descriptions overlapping those of the display device DD described with reference to FIG. 3 may be omitted or simplified.

The first light emitting area EA1, the second light emitting area EA2, and the third light emitting area EA3 may be repeatedly arranged along the first direction D1 and the second direction D2. According to some embodiments, the first and second light emitting areas EA1 and EA2 may be repeatedly arranged in odd columns along the second direction D2, and the third light emitting areas EA3 may be repeatedly arranged in even rows in the second direction D2.

For example, the first, second, and third light emitting areas EA1, EA2, and EA3 may be repeatedly arranged along the first direction D1 in a first row R1. Similarly, the first, second, and third light emitting areas EA1, EA2, and EA3 may be repeatedly arranged along the first direction D1 in a second row R2 adjacent to the first row R1. Meanwhile, the first and second light emitting areas EA1 and EA2 may be repeatedly arranged along the second direction D2 in a first column, and the third light emitting area EA3 may be repeatedly arranged along the second direction D2 in a second column adjacent to the first column. The arrangement of the light emitting areas may be repeated up to a row (e.g., a set or predetermined row) and a column (e.g., a set or predetermined column).

Areas of the first light emitting area EA1, the second light emitting area EA2, and the third light emitting area EA3 may be different from each other. According to some embodiments, the area of the first light emitting area EA1 that emits red light may be greater than the area of each of the second light emitting area EA2 that emits green light and the third light emitting area EA3 that emits blue light. In this case, the area of the second light emitting area EA2 may be greater than the area of the third light emitting area EA3. According to some embodiments, the area of the first light emitting area EA1 that emits red light may be the same as the area of the second light emitting area EA2 that emits green light and may be greater than the area of the third light emitting area EA3 that emits blue light.

According to some embodiments, the third light emitting area EA3 may have a rectangular planar shape, the first light emitting area EA1 may have an “L” shape planar shape rotated by about 90 degrees in a clockwise direction, and the second light emitting area EA2 may have an “L” shape planar shape rotated by about 90 degrees in a counterclockwise direction. For example, the first light emitting area EA1 may have a planar shape surrounding at least a part of the second light emitting area EA2, and the second light emitting area EA2 may have a planar shape surrounding at least a part of the first light emitting area EA1.

According to some embodiments, the first light emitting area EA1, the second light emitting area EA2, and the third light emitting area EA3 may at least partially overlap each other in the first direction D1. In addition, the first light emitting area EA1 and the second light emitting area EA2 may overlap each other in the second direction D2. That is, the third light emitting area EA3 may overlap the first and second light emitting areas EA1 and EA2 in the first direction D1 and may not overlap in the second direction D2.

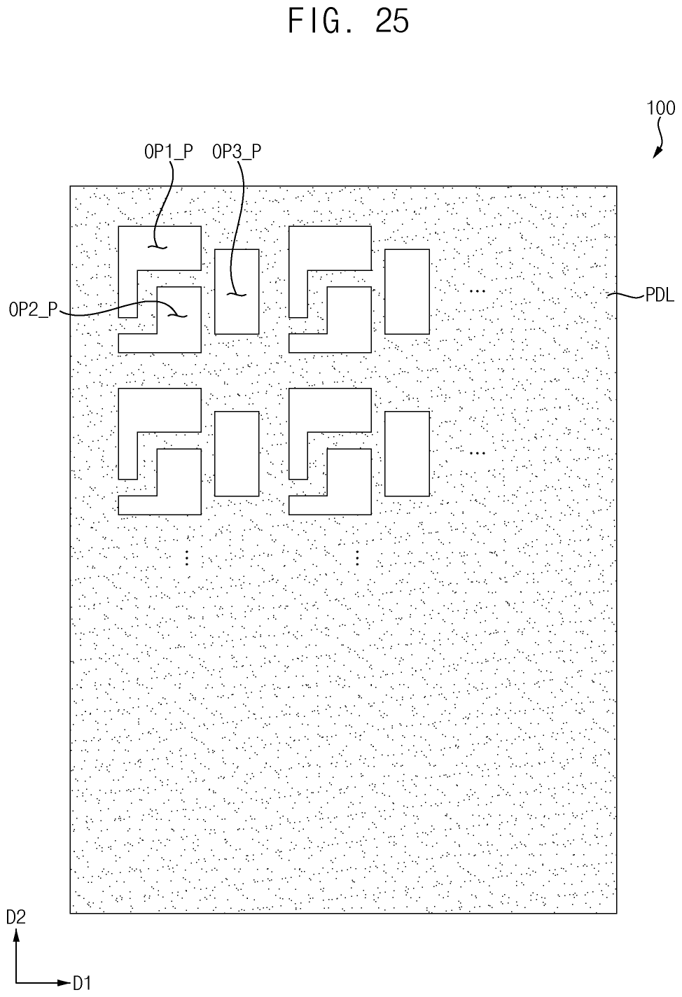

FIG. 25 is a plan view illustrating another example of a pixel defining layer of an array substrate of FIGS. 1 and 2.

Referring to FIGS. 1, 2 and 25, the array substrate 100 of the display device DD may include a pixel defining layer PDL. Hereinafter, some descriptions overlapping those of the array substrate 100 described with reference to FIG. 4 may be omitted or simplified.

According to some embodiments, a first opening OP1_P overlapping the first light emitting area EA1, a second opening OP2_P overlapping the second light emitting area EA2, and a third opening OP3_P overlapping the third light emitting area EA3 may be defined in the pixel defining layer PDL.

According to some embodiments, an area of the first opening OP1_P may be greater than the area of each of the second opening OP2_P and the third opening OP3_P. In this case, the area of the second opening OP2_P may be greater than the area of the third opening OP3_P. According to some embodiments, the area of the first opening OP1_P may be the same as the area of the second opening OP2_P and may be greater than the area of the third opening OP3_P. The first opening OP1_P may have the same area as the first light emitting area EA1, the second opening OP2_P may have the same area as the second light emitting area EA2, and the third opening OP3_P may have the same area as the third light emitting area EA3. Accordingly, the first opening OP1_P may define the first light emitting area EA1, the second opening OP2_P may define the second light emitting area EA2, and the third opening OP3_P may define the third light emitting area EA3.

However, embodiments of the present disclosure are not limited thereto, and the first opening OP1_P may have an area different from the area of the first light emitting area EA1, and the second opening OP2_P may have a different area than the area of the second light emitting area EA2. area, and the third opening OP3_P may have a different area from the area of the third light emitting area EA3.

According to some embodiments, the third opening OP3_P may have a rectangular planar shape, the first opening OP1_P may have an “L” shape planar shape rotated by about 90 degrees in a clockwise direction, and the second opening OP2_P may have an “L” shape planar shape rotated by about 90 degrees in a counterclockwise direction. That is, the first opening OP1_P may have the same planar shape as the first light emitting area EA1, the second opening OP2_P may have the same planar shape as the second light emitting area EA2, and the third opening OP3_P may have the same planar shape as the third light emitting area EA3.

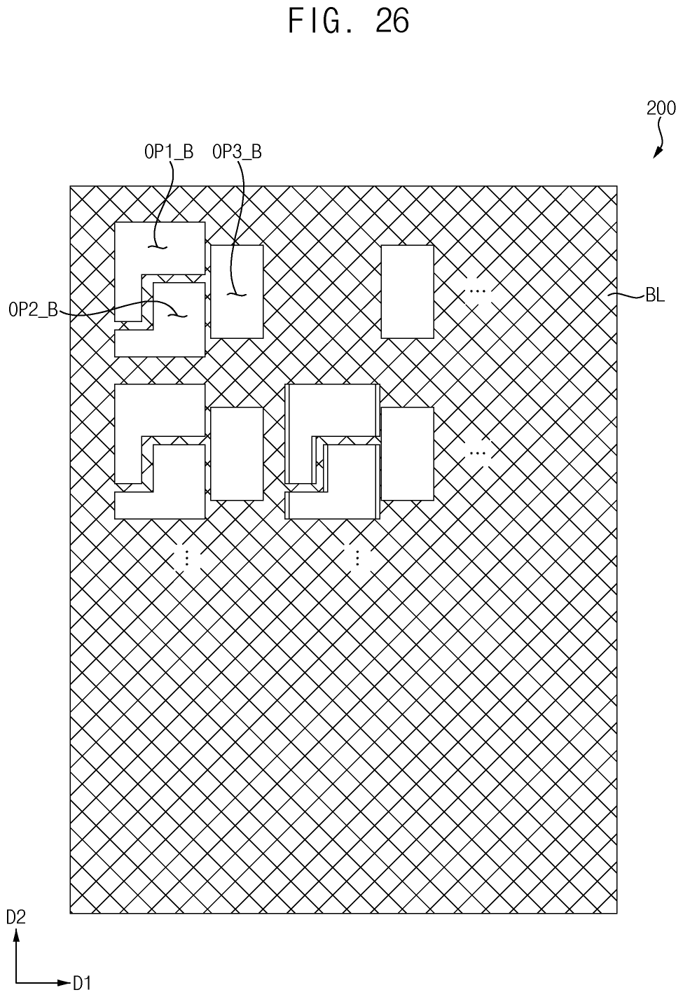

FIG. 26 is a plan view showing another example of a bank layer of a color conversion substrate of FIGS. 1 and 2.

Referring to FIGS. 1, 2, and 26, the color conversion substrate 200 of the display device DD may include a bank layer BL. Hereinafter, some descriptions overlapping with those of the color conversion substrate 200 described with reference to FIGS. 5 and 6 may be omitted or simplified.

According to some embodiments, a first opening OP1_B overlapping the first light emitting area EA1, a second opening OP2_B overlapping the second light emitting area EA2, and a third opening OP3_B overlapping the third light emitting area EA3 may be defined in the bank layer BL.

According to some embodiments, the area of the first opening OP1_B may be greater than the area each of the second opening OP2_B and the third opening OP3_B. In this case, the area of the second opening OP2_B may be greater than the area of the third opening OP3_B. According to some embodiments, the area of the first opening OP1_B may be the same as the area of the second opening OP2_B and may be greater than the area of the third opening OP3_B. The first opening OP1_B may have the area different from the area of the first light emitting area EA1, the second opening OP2_B may have the area different from the area of the second light emitting area EA2, and the third opening OP3_B may have the area different from the area of the third light emitting area EA3. For example, the first opening OP1_B may have a greater area than the first light emitting area EA1, the second opening OP2_B may have a greater area than the second light emitting area EA2, and the third opening OP3_B may have a greater area than the third light emitting area EA3.

However, embodiments of the present disclosure are not limited thereto, and the first opening OP1_B may have the same area as the first light emitting area EA1, and the second opening OP2_B may have the same area as the second light emitting area EA2, and the third opening OP3_B may have the same area as the third light emitting area EA3.

According to some embodiments, the third opening OP3_B may have a rectangular planar shape, the first opening OP1_B may have an “L” shape planar shape rotated by about 90 degrees in a clockwise direction, and the second opening OP2_B may have an “L” shape planar shape rotated by about 90 degrees in a counterclockwise direction. For example, the first opening OP1_B may have a planar shape surrounding at least a part of the second opening OP2_B, and the second opening OP2_B may have a planar shape surrounding at least a part of the first opening OP1_B. That is, the first opening OP1_B may have the same planar shape as the first light emitting area EA1, the second opening OP2_B may have the same planar shape as the second light emitting area EA2, and the third opening OP3_B may have the same planar shape as the third light emitting area EA3.

According to some embodiments, the first opening OP1_B, the second opening OP2_B, and the third opening OP3_B may at least partially overlap each other in the first direction D1. In addition, the first opening OP1_B and the second opening OP2_B may overlap each other in the second direction D2. That is, the third opening OP3_B may overlap the first and second openings OP1_B and OP2_B in the first direction D1 and may not overlap in the second direction D2.

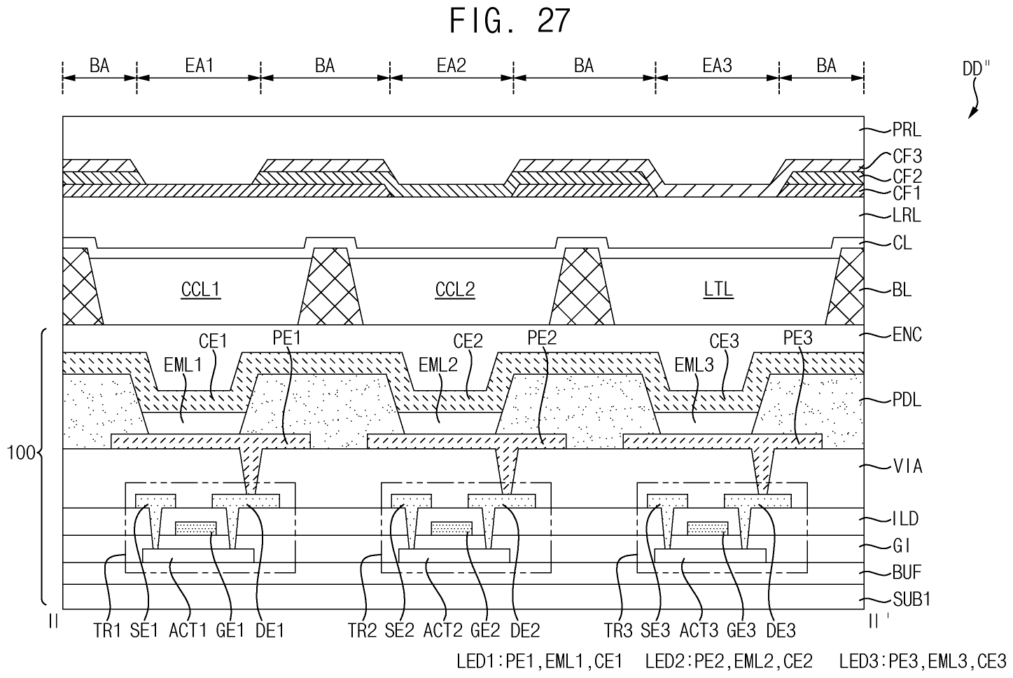

FIG. 27 is a cross-sectional view illustrating a display device according to some embodiments of the present disclosure.

Referring to FIG. 27, a display device DD′ according to some embodiments of the present disclosure may include a substrate SUB, a buffer layer BUF, first, second, and third transistors TR1, TR2, and TR3, a gate insulating layer GI, an interlayer insulating layer ILD, a via insulating layer VIA, a pixel defining layer PDL, first, second, and third light emitting elements LED1, LED2, and LED3, an encapsulation layer ENC, a bank layer BL, first and second color conversion layers CCL1 and CCL2, a light transmission layer LTL, a capping layer CL, a low refractive index layer LRL, first, second, and third color filters CF1, CF2, and CF3, and a protective layer PRL. Hereinafter, some descriptions overlapping those of the display device DD described with reference to FIGS. 7 and 8 may be omitted or simplified.

The display device DD′ according to some embodiments of the present disclosure may have a single substrate structure. For example, the bank layer BL, the first color conversion layer CCL1, the second color conversion layer CCL2, and the light transmission layer LTL may be directly located on the encapsulation layer ENC.

The capping layer CL may be located on the bank layer BL, the first color conversion layer CCL1, the second color conversion layer CCL2, and the light transmission layer LTL. The capping layer CL may cover the first bank layer BL, the first color conversion layer CCL1, the second color conversion layer CCL2, and the light transmission layer LTL. For example, the capping layer CL may include an inorganic material such as silicon oxide, silicon nitride, silicon oxynitride, and the like. These may be used alone or in combination with each other.

The low refractive index layer LRL may be located on the capping layer CL. The low refractive index layer LRL may have a relatively low refractive index. For example, the refractive index of the low refractive layer LRL may be lower than the refractive index of each of the first color conversion layer CCL1, the second color conversion layer CCL2, and the light transmission layer LTL. The low refractive index layer LRL may include an organic material. For example, the low refractive index layer LRL may include an organic polymer material including silicon.

A color filter layer may be located on the low refractive index layer LRL. The color filter layer may include the first color filter CF1, the second color filter CF2, and the third color filter CF3.

The first color filter CF1 may overlap the first light emitting area EA1 and the light blocking area BA, the second color filter CF2 may overlap the second light emitting area EA2 and the light blocking area BA, and the third color filter CF3 may overlap the third light emitting area EA3 and the light blocking area BA.

The protective layer PRL may be located on the first color filter CF1, the second color filter CF2, and the third color filter CF3. The protective layer PRL may cover the first color filter CF1, the second color filter CF2, and the third color filter CF3. The protective layer PRL may include an inorganic material and/or an organic material. For example, the protective layer PRL may include silicon oxide, silicon nitride, silicon oxynitride, and the like. These may be used alone or in combination with each other.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and characteristics of embodiments according to the present disclosure. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, and their equivalents.

What is claimed is:

1. A display device comprising:
a first substrate including a first light emitting area, a second light emitting area, and a third light emitting area that are configured to emit light of different colors, respectively;
a light emitting element on the first substrate and overlapping each of the first, second, and third light emitting areas;
a bank layer on the light emitting element and defining a first opening overlapping the first light emitting area, a second opening overlapping the second light emitting area, and a third opening overlapping the third light emitting area; and
an optical filter filling the first, second, and third openings,
wherein each of the first opening and the third opening has a rectangular planar shape and the second opening has an “L” shape planer shape.

2. The display device of claim 1, wherein the second opening has a planar shape surrounding at least a part of the third opening.

3. The display device of claim 1, wherein the second opening has an “L” shaped planar shape rotated clockwise by 90 degrees.

4. The display device of claim 1, wherein the first, second, and third openings at least partially overlap each other in a first direction and the third opening at least partially overlaps with the second opening in a second direction perpendicular to the first direction.

5. The display device of claim 4, wherein the second opening has a first area and a second area protruding from the first area in a direction opposite to the second direction, and
the third opening partially overlaps the first area in the second direction and partially overlaps the second area in the first direction.

6. The display device of claim 4, wherein the first light emitting area, the second light emitting area, and the third light emitting area are repeatedly arranged in an order of the first light emitting area, the second light emitting area, and the third light emitting area along the first direction.

7. The display device of claim 1, wherein the first emitting area has a same planar shape as the first opening, the second emitting area has a same planar shape as the second opening, and the third emitting area has a same planar shape as the third opening.

8. The display device of claim 1, wherein a width of the bank layer between two adjacent openings among the first, second, and third openings is 5 micrometers (μm) to 25 μm.

9. The display device of claim 1, wherein the first light emitting area is configured to emit red light, the second emitting area is configured to emit green light, and the third light emitting area is configured to emit blue light.

10. The display device of claim 9, wherein an area of the first light emitting area is greater than or equal to an area of the second light emitting area and the area of the second light emitting area is greater than an area of the third light emitting area.

11. The display device of claim 1, wherein the optical filter includes:
a first color conversion layer filling the first opening and including quantum dot;
a second color conversion layer filling the second opening and including quantum dot; and
a light transmission layer filling the third opening.

12. The display device of claim 11, further comprising:
a second substrate on the optical filter;
a first color filter between the second substrate and the first color conversion layer, and overlapping the first light emitting area;
a second color filter between the second substrate and the second color conversion layer, and overlapping the second light emitting area; and
a third color filter between the second substrate and the light transmission layer, and overlapping the second light emitting area.

13. The display device of claim 12, wherein a (1-1)th opening overlapping the second light emitting area and a (2-1)th opening overlapping the third light emitting area are defined in the first color filter,
a (1-2)th opening exposing a part of an upper surface of the first color filter in the first light emitting area and a (2-2)th opening connected to the (2-1)th opening are defined in the second color filter, and
a (1-3)th opening connected to the (1-1)th opening and a (2-3)th opening exposing a part of an upper surface of the second color filter in second light emitting area defined in the third color filter.

14. A display device comprising:
a first substrate including a first light emitting area, a second light emitting area, and a third light emitting area that are configured to emit light of different colors, respectively;
a light emitting element on the first substrate and overlapping each of the first, second, and third light emitting areas;
a bank layer on the light emitting element and defining a first opening overlapping the first light emitting area, a second opening overlapping the second light emitting area, and a third opening overlapping the third light emitting area; and
an optical filter filling the first, second, and third openings,
wherein the third opening has a rectangular planar shape and each of the first opening and the second opening has an “L” shaped planer shape.

15. The display device of claim 14, wherein the first opening has a planar shape surrounding at least a part of the second opening and the second opening has a planar shape surrounding at least a part of the first opening.

16. The display device of claim 14, wherein the second opening has an “L” shaped planar shape rotated by 180 degrees in a counterclockwise direction or a clockwise direction.

17. The display device of claim 14, wherein the first opening has an “L” shaped planar shape rotated 90 degrees clockwise and the second opening has an “L” shaped planar shape rotated 90 degrees counterclockwise direction.

18. The display device of claim 14, wherein the first, second, and third openings at least partially overlap each other in a first direction and the first and second openings at least partially overlap each other in a second direction perpendicular to the first direction.

19. The display device of claim 18, wherein the first and second light emitting areas are repeatedly arranged along the second direction in odd-numbered columns and the third light emitting area is repeatedly arranged along the second direction in even-numbered columns.

20. The display device of claim 14, wherein the first emitting area has a same planar shape as the first opening, the second emitting area has a same planar shape as the second opening, and the third emitting area has a same planar shape as the third opening.

21. The display device of claim 14, wherein the first light emitting area is configured to emit red light, the second emitting area is configured to emit green light, and the third light emitting area is configured to emit blue light.

22. The display device of claim 21, wherein an area of the first light emitting area is greater than or equal to an area of the second light emitting area and the area of the second light emitting area is greater than an area of the third light emitting area.

23. The display device of claim 14, wherein the optical filter includes:
a first color conversion layer filling the first opening and including quantum dot;
a second color conversion layer filling the second opening and including quantum dot; and
a light transmission layer filling the third opening.

24. The display device of claim 23, further comprising:
a second substrate on the optical filter;
a first color filter between the second substrate and the first color conversion layer, and overlapping the first light emitting area;
a second color filter between the second substrate and the second color conversion layer, and overlapping the second light emitting area; and
a third color filter between the second substrate and the light transmission layer, and overlapping the second light emitting area.
